(19) United States
(12) Patent Application Publication
(10) Pub. No.: US 2018/0157176 A1
(43) Pub. Date: Jun. 7, 2018

(54) LITHOGRAPHIC PRINTING PLATE PRECURSOR AND USE

(71) Applicant: Eastman Kodak Company, Rochester, NY (US)

(72) Inventors: Masamichi Kamiya, Oura-gun (JP); Yuuki Torihata, Tatebayashi-shi (JP); Akira lgarashi, Kumagaya-shi (JP); Koji Hayashi, Tatebayashi-shi (JP); Jianbing Huang, Trumbull, CT (US)

(21) Appl. No.: 15/788,831

(22) Filed: Oct. 20, 2017

Related U.S. Application Data
(63) Continuation-in-part of application No. 15/367,357, filed on Dec. 2, 2016, now abandoned.

(51) Int. Cl. G03F 7/105; G03F 7/004; G03F 7/029; G03F 7/30

(52) U.S. Cl. CPC G03F 7/105; G03F 7/004; G03F 7/3035; G03F 7/3078; G03F 7/029

(57) ABSTRACT

A lithographic printing plate precursor has a substrate comprising a hydrophilic surface and two opposing edges; a radiation-sensitive imagable layer, and optionally, a protective layer disposed over that layer. The precursor has a shear droop at each opposing edge, each shear droop having a shear droop depth Y of 20-200 μm and a shear droop width X of 500-2000 μm. The precursor also has a hydrophilic coating band extending from each of the two opposing edges inwardly along the hydrophilic surface independently to provide a hydrophilic coating band width A of at least 1.5 times the shear droop width X. This hydrophilic coating band comprises amphoteric surfactant(s) in an amount greater than all other surfactants. Such individual precursors are obtained by cutting a continuous radiation-sensitive web into strips and such cutting creates the shear droop that can result in edge staining if the hydrophilic coating band is not present.

### CROSS-REFERENCE TO RELATED APPLICATIONS

This application is a continuation-in-part of pending U.S. patent application Ser. No. 15/367,357, filed Dec. 2, 2016, and now ______, the disclosure of which is hereby incorporated herein by reference in its entirety

### FIELD OF THE INVENTION

This invention relates to a negative-working lithographic printing plate precursor that can be imaged using radiation and processed to provide a lithographic printing plate. This invention also relates to a method for imaging and processing such negative-working lithographic printing plate precursors.

### BACKGROUND OF THE INVENTION

In lithographic printing, lithographic ink receptive regions, known as image areas, are generated on a hydrophilic surface of a planar substrate. When the printing plate surface is moistened with water and a lithographic printing ink is applied, hydrophilic regions retain the water and repel the lithographic printing ink, and the lithographic ink receptive image regions accept the lithographic printing ink and repel the water. The lithographic printing ink is transferred to the surface of a material upon which the image is to be reproduced, perhaps with the use of a blanket roller.

Negative-working lithographic printing plate precursors useful to prepare lithographic printing plates typically comprise a negative-working radiation-sensitive imagable layer disposed over the hydrophilic surface of a substrate. Such an imagable layer includes radiation-sensitive components that can be dispersed in a suitable polymeric binder material. After the precursor is imagewise exposed to suitable radiation to form exposed regions and non-exposed regions, the non-exposed regions of the imagable layer are removed by a suitable developer, revealing the underlying hydrophilic surface of the substrate. The exposed regions of the imagable layer that are not removed are lithographic ink-receptive, and the hydrophilic substrate surface revealed by the developing process accept water and aqueous solutions such as a fountain solution, and repel lithographic printing ink.

Radiation-sensitive photopolymerizable compositions used in negative-working lithographic printing plate precursors typically comprise free-radically polymerizable components, one or more radiation absorbers, an initiator composition, and optionally one or more polymeric binders. In recent years, there has been a desire in the lithographic printing industry for simplification in making lithographic printing plates by carrying out development on press (“DOP”) using a lithographic printing ink or fountain solution, or both, to remove non-exposed regions of the imagable layer.

Independently of the type of lithographic printing plate precursor, lithography has generally been carried out using a planar metal substrate composed for example of aluminum or an aluminum alloy. The surface of the metal substrate intended for imaging is generally roughened by surface graining to ensure good adhesion to an overlying hydrophobic imagable layer and treated to acidic anodization to form an aluminum oxide (“anodic oxide”) layer or coating to improve abrasion resistance during lithographic printing, adhesion to overlying imagable layer, and surface hydrophilicity during printing. Oxide pores formed during anodization can be at least partially sealed with a hydrophilic post-treatment before an imagable layer formation is applied.

During lithographic printing of certain materials such as books, magazines, and other commercial materials, the outermost edges of the lithographic printing plate is typically not used for printing because the width of the printable stock is narrower than the width of the lithographic printing plate. However, in printing newspapers, the opposite is typically true, namely the lithographic printing plate is narrower than the width of newspaper stock. During lithographic printing of a continuous roll of newspaper stock, lithographic printing ink can be transferred by the edges of the lithographic printing plate to the newspaper stock in the form of an “edge stain” leading to an unsightly ink line near the edge of the newspaper pages.

This problem has been addressed in the industry in various ways. For example, a “desensitizing” solution can be applied near the outermost edges to minimize ink acceptance, and such desensitizing solutions can contain a phosphoric acid polymer or hexametaphosphoric acid salt as described in Japanese Patent Publications 1999(11)-052579 (Aono) and 2003-255519 (Aoshima). Alternatively, the lithographic printing plate opposing edges can be cut during manufacturing in a configuration such that the printing plate edges are bent downward to provide certain curvature from horizontal (called a “shear droop”) to minimize ink buildup at the opposing edge regions, as described for example in WO 2015/129504 (Wariishi et al.).

In other instances, the problem is addressed by both forming a shear droop at the opposing edges and coating those curved edge regions with a desensitizing solution containing a hydrophilic organic polymer such as gum arabic or a cellulosic material in combination with an anionic, cationic, or nonionic surfactant as described in EP 2,735,444A2 (Wariishi et al.). There is no teaching in this publication about the use of amphoteric surfactants in an amount greater than all other types of surfactants to solve the noted problem.

While forming a shear droop on the opposing edges of the lithographic printing plate precursor can reduce the edge stain problem during printing, bending the opposing edges can lead to a different problem. Where the shear droop is formed, cracks can form in the hydrophilic anodic oxide layer on the substrate under the imagable layer. These anodic oxide layer cracks can pick up excess lithographic printing ink during the printing process in the curved surface regions of the shear droop, which excess lithographic printing ink can form unwanted edge lines in printed materials.

In the present application, the term “edge scumming” is meant to refer to the edge lines on printed materials caused by the curved surface regions of the shear droop, and the term “edge stain” is used to refer to the edge lines on the printed materials caused by the sharp corner formed between the hydrophilic surface of a substrate and the surface that is formed during cutting. The greater the distance the shear droop region is extended inward from the opposing edges, the greater the potential for crack formation in the anodic oxide layer and unwanted lithographic printing ink build-up and unsightly ink lines on the edges of printed newspaper pages.

There is a need to minimize or eliminate both lithographic printing ink stain and edge scumming particularly where the shear droop regions are extended inward from the opposing edges of the lithographic printing plate.

### SUMMARY OF THE INVENTION

The present invention provides a lithographic printing plate precursor comprising:

a substrate comprising a hydrophilic surface and two opposing edges having edge surfaces;

a radiation-sensitive imagable layer that is disposed on the hydrophilic surface of the substrate, the radiation-sensitive imagable layer comprising:
one or more free radically polymerizable components, an initiator composition that provides free radicals upon exposure of the radiation sensitive imagable layer to radiation,
one or more radiation absorbers, and
optionally, a polymeric binder different from the one or more free radically polymerizable components;

wherein the lithographic printing plate precursor has a shear droop at each of the two opposing edges, which shear droop has a shear droop depth Y of at least 20 μm and up to and including 200 μm, and a shear droop width X of at least 500 μm and up to and including 2000 μm, and

wherein the lithographic printing plate precursor further comprises a band of a hydrophilic coating disposed over the radiation-sensitive imagable layer and any protective layer disposed thereon, which hydrophilic coating band extends from each of the two opposing edges inwardly along the hydrophilic surface independently for a hydrophilic coating band width A of at least 1.5 times the shear droop width X, wherein the hydrophilic coating band comprises one or more amphoteric surfactants in a total amount of at least 5 weight % and up to and including 90 weight %, based on the total dry weight of the hydrophilic coating band, which total amount of the one or more amphoteric surfactants is greater than the total of all cationic, anionic, and anionic surfactants in the hydrophilic coating band,

and the lithographic printing plate precursor optionally comprises a protective layer disposed over the radiation-sensitive imagable layer.

This invention also provides a method for forming a lithographic printing plate, comprising:

A) imagewise exposing a lithographic printing plate precursor according to any embodiment of the present invention with radiation, to provide imagewise exposed regions and non-imagewise exposed regions in the radiation-sensitive imagable layer; and

B) removing the non-imagewise exposed regions of the radiation-sensitive imagable layer.

In addition, the present invention provides a method of preparing one or more lithographic printing plate precursors, the method comprising:

A) applying a radiation-sensitive imagable layer formulation to a hydrophilic surface of a continuous substrate web having a longitudinal dimension along the continuous substrate web and a lateral dimension across the continuous substrate web, the radiation-sensitive imagable layer formulation comprising:
one or more free radically polymerizable components, an initiator composition that provides free radicals upon exposure of the radiation sensitive imagable-layer to radiation,
one or more radiation absorbers, and
optionally, a polymeric binder different from the one or more free radically polymerizable components,

to form a continuous radiation-sensitive web having a radiation-sensitive imagable layer disposed on the hydrophilic surface of the continuous substrate web;

B) optionally applying a protective layer formulation over the radiation-sensitive imagable layer to form a protective layer thereon;

C) cutting the continuous radiation-sensitive web in direction of the longitudinal dimension to form one or more radiation-sensitive strips, each of which is narrower than the width of the continuous radiation-sensitive web and has two opposing edges where cutting has occurred, and each opposing edge having a shear droop having a shear droop depth Y of at least 20 μm and up to and including 200 μm, and a shear droop width X of at least 500 μm and up to and including 2000 μm;

D) forming a band of a hydrophilic coating from a hydrophilic coating formulation over the radiation-sensitive imagable layer and any protective layer disposed thereon, such that the hydrophilic coating band extends from each of the two opposing edges inwardly along the hydrophilic surface independently for hydrophilic coating band width A of at least 1.5 times the shear droop width X,

wherein the hydrophilic coating formulation comprises one or more amphoteric surfactants; and

E) cutting the one or more radiation-sensitive strips in direction of the lateral dimension into one or more individual radiation-sensitive lithographic printing plate precursors.

In some embodiments, features A), B), C), D), and E) are all carried out in the recited sequence while in other embodiments, only A), C), D), and E) are carried out sequence [wherein B) is omitted].

The lithographic printing plate precursor of the present invention has features that reduce the tendency of both edge stain and edge scumming that is evident during use of prior art precursors during lithographic printing. This improvement is achieved by reducing the tendency of anodic oxide cracks in the substrate from picking up excess lithographic printing ink during the lithographic printing process, even though the precursor has a shear droop at opposing edges that extends a considerable distance from each of the opposing edges. The noted problems have been solved by providing a band of a unique hydrophilic coating along the opposing edges having the shear droop, which hydrophilic coating band contains one or more amphoteric surfactants that are desirably used in combination with one or more hydrophilic film-forming polymers. The total amount of amphoteric surfactants in the hydrophilic coating is necessarily greater than the total of all anionic, cationic, and nonionic surfactants so that both edge stain and edge scumming are minimized.

Further advantages and benefits of the present invention will be evident from the teaching and working Examples provided below.

### DETAILED DESCRIPTION OF THE DRAWING

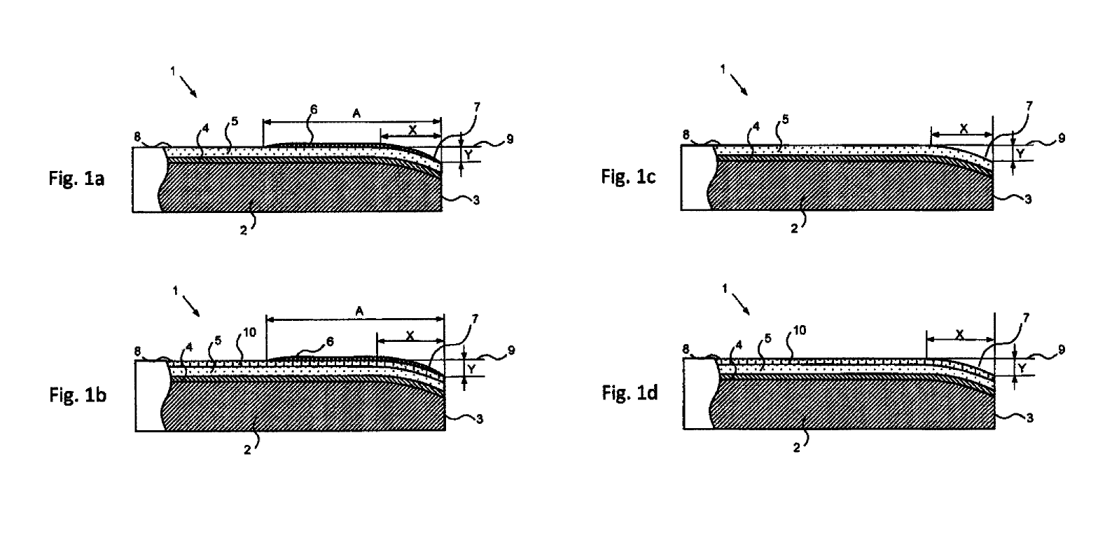

FIGS. 1a, 1b, 1c, and 1d illustrate partial cross-sectional views of lithographic printing plate precursors having a shear droop at one opposing edge.

FIGS. 1a and 1b illustrate embodiments of the present invention while FIGS. 1c and 1d illustrate embodiments outside the present invention.

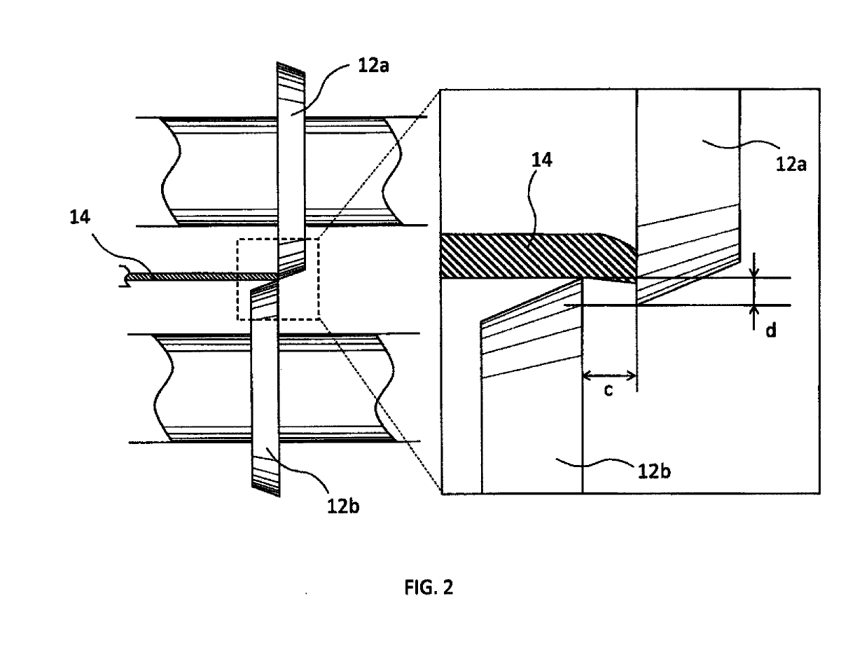

FIG. 2 is a partial schematic view of a set of two opposing rotary blades used to cut a continuous radiation-sensitive web to provide radiation-sensitive strips according to the present invention.

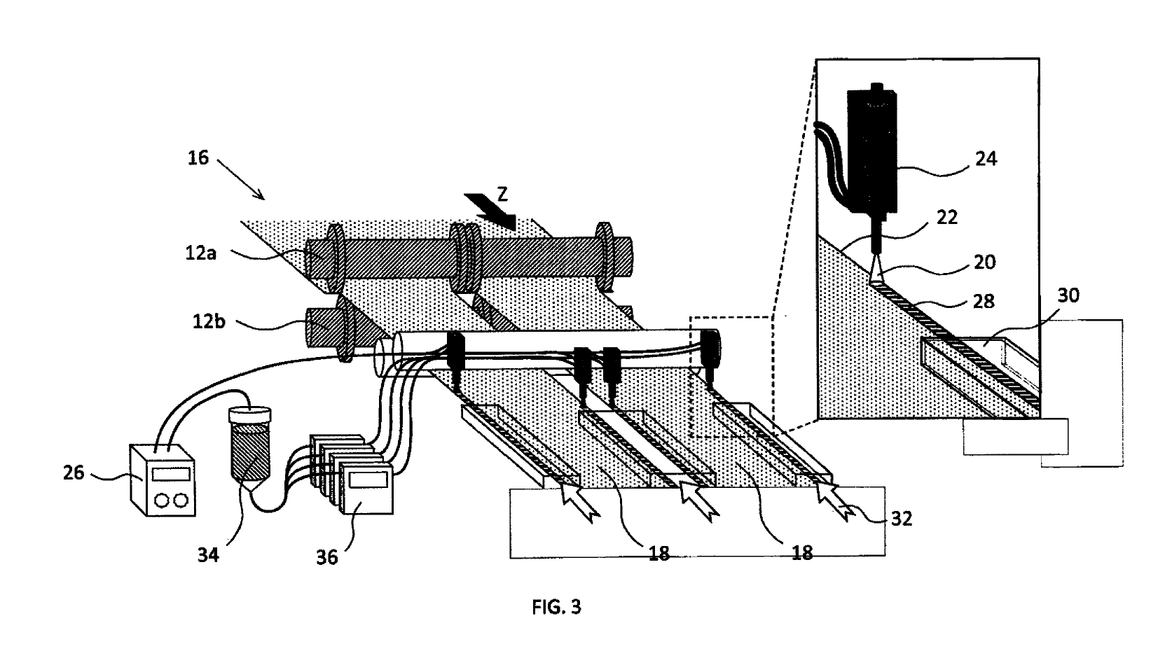

FIG. 3 is a schematic view of a slitting device that can include multiple sets of opposing rotary blades as illustrated in FIG. 2, and that is useful in preparing radiation-sensitive strips and individual lithographic printing plate precursors according to the present invention.

### DETAILED DESCRIPTION OF THE INVENTION

The following discussion is directed to various embodiments of the present invention and while some embodiments can be desirable for specific uses, the disclosed embodiments should not be interpreted or otherwise considered to limit the scope of the present invention, as claimed below. In addition, one skilled in the art will understand that the following disclosure has broader application than is explicitly described in the discussion of any embodiment.

### Definitions

As used herein to define various components of the hydrophilic coating formulation, radiation-sensitive imagable layer formulation, protective layer formulation, and other materials used in the practice of this invention, unless otherwise indicated, the singular forms “a,” “an,” and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term should be interpreted to have a standard dictionary meaning.

The use of numerical values in the various ranges specified herein, unless otherwise expressly indicated otherwise, are considered to be approximations as though the minimum and maximum values within the stated ranges were both preceded by the word “about.” In this manner, slight variations above and below the stated ranges may be useful to achieve substantially the same results as the values within the ranges. In addition, the disclosure of these ranges is intended as a continuous range including every value between the minimum and maximum values as well as the end points of the ranges.

Unless the context indicates otherwise, when used herein, the terms “negative-working, radiation-sensitive lithographic printing plate precursor,” “precursor,” and “lithographic printing plate precursor” are meant to be equivalent references to embodiments of the present invention.

The term “support” is used herein to refer to an aluminum-containing material (web, strip, sheet, foil, or other form) that can be then treated or coated to prepare a “substrate” that refers to a hydrophilic article having a hydrophilic planar surface upon which various layers, including a hydrophilic anodic oxide layer, a radiation-sensitive imagable layer, and an optional protective layer are disposed. The term “web” is used to describe a rectangular sheet whose longitudinal dimension is larger than its lateral dimension by a factor of 10 or more. The term “continuous web” refers to a web that is moved continuously while being treated by substantially stationary treatment equipment during the manufacture of the individual precursors. The term “longitudinal dimension” refers to the direction along the length of the rectangular sheet and the term “lateral dimension” refers to the direction across the width of the rectangular sheet. The term “strip” has the same meaning as the term web except that it is used herein as a derivative of the web because of cutting. The terms “rectangle”, “rectangular shape” and “rectangular form” refer to a parallelogram with four angles of equal sizes and include square, which is a special rectangle with four sides of equal length.

As used herein, the term “infrared radiation absorber” refers to a compound or material that absorbs electromagnetic radiation in the infrared region and typically refers to compounds or materials that have an absorption maximum in the infrared region.

As used herein, the term “infrared region” refers to radiation having a wavelength of at least 750 nm and higher. In most instances, the term “infrared” is used to refer to the “near-infrared” region of the electromagnetic spectrum that is defined herein to be at least 750 nm and up to and including 1400 nm.

As used herein, the term “radiation absorber” refers to a compound or material that absorbs electromagnetic radiation in the ultraviolet region and higher, that is radiation having a wavelength of at least 200 nm and higher, for example a compound or mixture of compounds that absorb any or all of UV, visible, and infrared radiation.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

As used herein, the term “polymer” is used to describe compounds with relatively large molecular weights formed by linking together many small reacted monomers. As the polymer chain grows, it folds back on itself in a random fashion to form coiled structures. With the choice of solvents, a polymer can become insoluble as the chain length grows and become polymeric particles dispersed in the solvent medium. These particle dispersions can be very stable and useful in radiation-sensitive imagable layers described for use in the present invention. In this invention, unless indicated otherwise, the term “polymer” refers to a non-crosslinked material. Thus, crosslinked polymeric particles differ from the non-crosslinked polymeric particles in that the latter can be dissolved in certain organic solvents of good solvating property whereas the crosslinked polymeric particles may swell but do not dissolve in the organic solvent because the polymer chains are connected by strong covalent bonds.

The term “copolymer” refers to polymers composed of two or more different repeating or recurring units that are arranged along the polymer backbone.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers.

Recurring units in polymeric binders described herein are generally derived from the corresponding ethylenically unsaturated polymerizable monomers used in a polymerization process, which ethylenically unsaturated polymerizable monomers can be obtained from various commercial sources or prepared using known chemical synthetic methods.

As used herein, the term “ethylenically unsaturated polymerizable monomer” refers to a compound comprising one or more ethylenically unsaturated (—C═C—) bonds that are polymerizable using free radical or acid-catalyzed polymerization reactions and conditions. It is not meant to refer to chemical compounds that have only unsaturated —C═C— bonds that are not polymerizable under these conditions.

Unless otherwise indicated, the term “weight %” refers to the amount of a component or material based on the total solids of a composition, formulation, or layer. Unless otherwise indicated, the percentages can be the same for either a dry layer or the total solids of the formulation or composition.

As used herein, the term “layer” or “coating” can consist of one disposed or applied layer or a combination of several sequentially disposed or applied layers. If a layer is considered infrared radiation-sensitive and negative-working, it is both sensitive to radiation (as described above for “radiation-absorber”) and negative-working in the formation of lithographic printing plates.

The terms “edge scumming” and “edge stain” are defined above in the Background of the Invention.

### Uses

The lithographic printing plate precursors of the present invention are useful for forming lithographic printing plates for lithographic printing using a lithographic printing ink and fountain solution. These precursors are prepared with the structure and components described as follows. In addition, the present invention is useful for preparing such lithographic printing plates by imagewise exposing and processing the exposed precursor off-press using a suitable developer or on-press using a lithographic printing ink, a fountain solution, or a combination of a lithographic printing ink and a fountain solution as described below. The present invention is also useful in a manufacturing process for preparing the inventive lithographic printing plate precursors.

### Substrate

The substrate that is present in the precursors of this invention generally has a hydrophilic imaging-side planar surface, or at least a surface that is more hydrophilic than the applied radiation-sensitive imagable layer on the imaging side of the substrate. The substrate comprises a support that can be composed of any material that is conventionally used to prepare lithographic printing plate precursors.

One useful substrate is composed of an aluminum-containing support that can be treated using techniques known in the art, including roughening of some type by physical (mechanical) graining, electrochemical graining, or chemical graining, which is followed by anodizing. Anodizing is typically done using phosphoric or sulfuric acid and conventional procedures to form a desired hydrophilic aluminum oxide (or anodic oxide) layer or coating on the aluminum-containing support, which aluminum oxide (anodic oxide) layer can comprise a single layer or a composite of multiple layers having multiple pores with varying depths and shapes of pore openings. Such processes thus provide an anodic oxide layer underneath a radiation-sensitive imagable layer that can be provided as described below. A discussion of such pores and a process for controlling their width is described for example in U.S. Patent Publication 2013/0052582 (Hayashi) the disclosure of which is incorporated herein by reference.

Sulfuric acid anodization of the aluminum support generally provides an aluminum (anodic) oxide weight (coverage) on the surface of at least 1 g/m² and up to and including 5 g/m² and more typically of at least 3 g/m² and up to and including 4 g/m². Phosphoric acid anodization generally provides an aluminum (anodic) oxide weight on the surface of from at least 0.5 g/m² and up to and including 5 g/m² and more typically of at least 1 g/m² and up to and including 3 g/m².

An anodized aluminum support can be treated further to seal the anodic oxide pores or to further hydrophilize its surface, or both, using known post-anodic treatment (PAT) processes, such as post-treatments in aqueous solutions of poly(vinyl phosphonic acid) (PVPA), vinyl phosphonic acid copolymers, poly[(meth)acrylic acid] or its alkali metal salts, or acrylic acid copolymers or their alkali metal salts, mixtures of phosphate and fluoride salts, or sodium silicate. The PAT process materials can also comprise unsaturated double bonds selectively enhance adhesion between the treated surface and the radiation-sensitive imagable layer in the radiation exposed regions. Such unsaturated double bonds can be provided in low molecular weight materials or they can be present within side chains of polymers. Useful post-treatment processes include dipping the substrate with rinsing, dipping the substrate without rinsing, and various coating techniques such as extrusion coating.

For example, as noted in the cited Hayashi publication, an anodized substrate can be treated with an alkaline or acidic pore-widening solution to provide an anodic oxide layer containing columnar pores so that the diameter of the columnar pores at their outermost surface is at least 90% of the average diameter of the columnar pores. In some embodiments, the treated substrate can comprise a hydrophilic layer disposed directly on a grained, anodized, and post-treated aluminum-containing support, and such hydrophilic layer can comprise a non-crosslinked hydrophilic polymer having carboxylic acid side chains.

The thickness of a substrate can be varied but should be sufficient to sustain the wear from printing and thin enough to wrap around a printing form. Useful embodiments include a treated aluminum foil having a thickness of at least 100 μm and up to and including 700 μm. The backside (non-imaging side) of the substrate can be coated with antistatic agents, a slipping layer, or a matte layer to improve handling and “feel” of the precursor.

As discussed in more detail below, the substrate is generally formed as a continuous roll (or continuous web) of sheet material that is suitably coated with a radiation-sensitive imagable layer formulation and optionally a protective layer formulation, followed by slitting or cutting (or both) to size to provide individual lithographic printing plate precursors having a shape or form having four right-angled corners (thus, typically in a square or rectangular shape or form). Typically, the cut individual precursors have a planar or generally flat rectangular shape.

### Radiation-Sensitive Imagable Layer

The precursors of the present invention can be formed by suitable application of a negative-working radiation-sensitive composition as described below to a suitable substrate (as described above) to form a radiation-sensitive imagable layer that is negative-working on that substrate. In general, the radiation-sensitive composition (and resulting radiation-sensitive imagable layer) comprises one or more free radically polymerizable components, one or more radiation absorbers, and an initiator composition that provides free radicals upon exposure to imaging radiation as essential components, and optionally, a polymeric binder different from the one or more free radically polymerizable components, all of which essential and optional components are described in more detail below. There is generally only a single radiation-sensitive imagable layer in the precursor. It is generally the outermost layer in the precursor, but in some embodiments, there can be an outermost water-soluble hydrophilic protective layer (also known as a topcoat or oxygen barrier layer) disposed over the radiation-sensitive imagable layer.

The radiation-sensitive composition (and radiation-sensitive imagable layer prepared therefrom) comprises one or more free radically polymerizable components, each of which contains one or more free radically polymerizable groups (and two or more of such groups in some embodiments) that can be polymerized using free radical initiation. In some embodiments, the radiation-sensitive imagable layer comprises two or more free radically polymerizable components having the same or different numbers of free radically polymerizable groups in each molecule.

Useful free radically polymerizable components can contain one or more free radical polymerizable monomers or oligomers having one or more addition polymerizable ethylenically unsaturated groups (for example, two or more of such groups). Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

It is possible for one or more free radically polymerizable components to have large enough molecular weight or to have sufficient polymerizable groups to provide a crosslinkable polymer matrix that functions as a “polymeric binder” for other components in the radiation-sensitive imagable layer. In such embodiments, a separate non-polymerizable or non-crosslinkable polymer binder (described below) is not necessary but still may be present.

Free radically polymerizable components include urea urethane (meth)acrylates or urethane (meth)acrylates having multiple (two or more) polymerizable groups. Mixtures of such compounds can be used, each compound having two or more unsaturated polymerizable groups, and some of the compounds having three, four, or more unsaturated polymerizable groups. For example, a free radically polymerizable component can be prepared by reacting DESMODUR® N 100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP U.S. Pat. No. 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.) the disclosures of all of which are incorporated herein by reference. Other useful free radically polymerizable components include those described in U.S. Patent Application Publication 2009/0142695 (Baumann et al.), which radically polymerizable components include 1H-tetrazole groups, and the disclosure of which is incorporated herein by reference.

The one or more free radically polymerizable components are generally present in a radiation-sensitive imagable layer in an amount of at least 10 weight % and up to and including 70 weight %, or typically of at least 20 weight % and up to and including 50 weight %, all based on the total dry weight of the radiation-sensitive imagable layer.

In addition, the radiation-sensitive imagable layer also comprises one or more radiation absorbers to provide desired radiation sensitivity or to convert radiation to heat, or both. In some embodiments, the one or more radiation absorbers are one or more different infrared radiation absorbers located in an infrared radiation-sensitive imagable layer so that the lithographic printing plate precursors can be imaged with infrared radiation-emitting lasers. The present invention is also applicable to lithographic printing plate precursors designed for imaging with violet lasers having emission peaks at around 405 nm, with visible lasers such as those having emission peaks around 488 nm or 532 nm, or with UV radiation having significant emission peaks below 400 nm. In such embodiments, the radiation absorbers can be selected to match the radiation source and many useful examples are known in the art.

The total amount of one or more radiation absorbers is at least 0.5 weight % and up to and including 30 weight %, or typically of at least 1 weight % and up to and including 15 weight %, based on the total dry weight of the radiation-sensitive imagable layer.

Useful infrared radiation absorbers can be pigments or infrared radiation absorbing dyes. Suitable dyes also those described in for example, U.S. Pat. No. 5,208,135 (Patel et al.), U.S. Pat. No. 6,153,356 (Urano et al.), U.S. Pat. No. 6,309,792 (Hauck et al.), U.S. Pat. No. 6,569,603 (Furukawa), U.S. Pat. No. 6,797,449 (Nakamura et al.), U.S. Pat. No. 7,018,775 (Tao), U.S. Pat. No. 7,368,215 (Munnelly et al.), U.S. Pat. No. 8,632,941 (Balbinot et al.), and U.S. Patent Application Publication 2007/056457 (Iwai et al.), the disclosures of all of which are incorporated herein by reference. In some infrared radiation-sensitive embodiments, it is desirable that at least one infrared radiation absorber in the infrared radiation-sensitive imagable layer be a cyanine dye comprising a tetraarylborate anion such as a tetraphenylborate anion. Examples of such dyes include those described in United States Patent Application Publication 2011/003123 (Simpson et al.) the disclosure of which is incorporated herein by reference.

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

The radiation-sensitive imagable layer also includes an initiator composition that provides free radicals upon exposure of the radiation-sensitive imagable layer to infrared radiation to initiate the polymerization of the one or more free radically polymerizable components. The initiator composition can be a single compound or a combination or system of a plurality of compounds.

Particularly useful compounds in the initiator composition are onium salts, each of which comprises a cation having at least one onium ion atom in the molecule, and an anion. Examples of the onium ion atom in the onium salt include sulfonium, iodonium, ammonium, phosphonium, and diazonium. Examples of the onium salts include triphenylsulfonium, diphenyliodonium, diphenyldiazonium, and derivatives obtained by introducing one or more substituents into the benzene ring of these compounds. Suitable substituents include but are not limited to, alkyl, alkoxy, alkoxycarbonyl, acyl, acyloxy, chloro, bromo, fluoro and nitro groups.

Examples of anions in the onium salts include but are not limited to, halogen anions, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, CIC₆H₄SO₃⁻, and boron anion as described for example in U.S. Pat. No. 7,524,614 (Tao et al.), the disclosure of which is incorporated herein by reference.

The onium salt can be obtained by combining an onium salt having sulfonium in the molecule with an onium salt in the molecule. The onium salt can be a polyvalent onium salt having at least two onium ion atoms in the molecule that are bonded through a covalent bond. Among polyvalent onium salts, those having at least two onium ion atoms in the molecule are useful and those having a sulfonium or iodonium cation in the molecule are particularly useful. Representative polyvalent onium salts are represented by the following formulas (6) and (7):

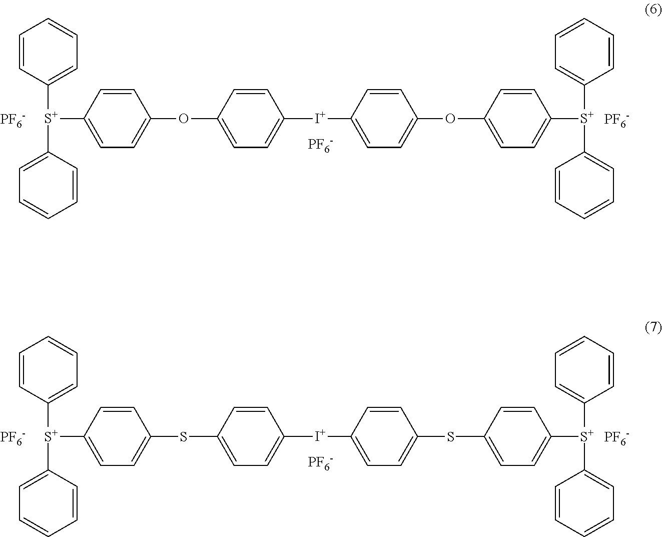

Furthermore, the onium salts described in paragraphs [0033] to [0038] of the specification of Japanese Patent Publication 2002-082429 [or U.S. Patent Application Publication 2002-0051934 (Ippei et al.), the disclosure of which is incorporated herein by reference] or the iodonium borate complexes described in U.S. Pat. No. 7,524,614 (noted above), can also be used in the present invention.

In some embodiments, the initiator composition can comprise a combination of initiator compounds such as a combination of iodonium salts, for example the combination of Compound A and Compound B described as follows.

Compound A can be represented by Structure (I) shown below, and the one or more compounds collectively known as compound B can be represented below by either Structure (II) or (III):

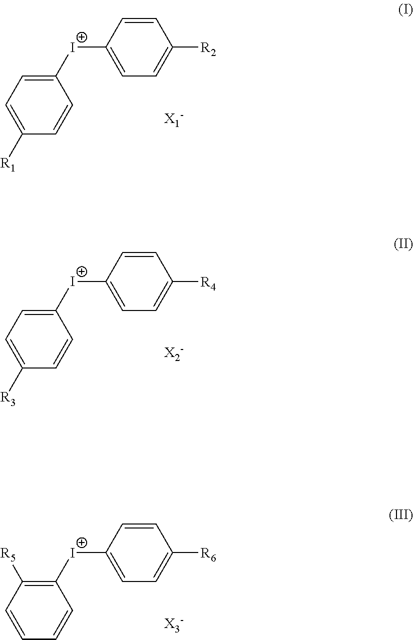

In these Structures (I), (II), and (III), R₁, R₂, R₃, R₄, R₅ and R₆ are independently substituted or unsubstituted alkyl groups or substituted or unsubstituted alkoxy groups, each of these alkyl or alkoxy groups having from 2 to 9 carbon atoms (or particularly from 3 to 6 carbon atoms). These substituted or unsubstituted alkyl and alkoxy groups can be in linear or branched form. In many useful embodiments, R₁, R₂, R₃, R₄, R₅ and R₆ are independently substituted or unsubstituted alkyl groups, such as independently chosen substituted or unsubstituted alkyl groups having 3 to 6 carbon atoms.

In addition, at least one of R₃ and R₄ can be different from R₁ or R₂; the difference between the total number of carbon atoms in R₁ and R₂ and the total number of carbon atoms in R₃ and R₄ is 0 to 4 (that is, 0, 1, 2, 3, or 4); the difference between the total number (sum) of carbon atoms in R₁ and R₂ and the total number (sum) of carbon atoms in R₅ and R₆ is 0 to 4 (that is, 0, 1, 2, 3, or 4); and X₁, X₂ and X₃ are the same or different anions.

Useful anions include but are not limited to, ClO₄⁻, PF₆⁻, BF₄⁻, SbFb⁻, CH₃SO₃⁻, CF₃SO₃⁻, C₆H₅SO₃⁻, CH₃C₆H₄SO₃⁻, HOC₆H₄SO₃⁻, ClC₆H₄SO₃⁻, and borate anions represented by the following Structure (IV):

B—(R¹)(R²)(R³)(R⁴) (IV)

wherein R¹, R², R³, and R⁴ independently represent substituted or unsubstituted alkyl, substituted or unsubstituted aryl (including halogen-substituted aryl groups), substituted or unsubstituted alkenyl, substituted or unsubstituted alkynyl, substituted or unsubstituted cycloalkyl, or substituted or unsubstituted heterocyclic groups, or two or more of R¹, R², R³, and R⁴ can be joined together to form a substituted or unsubstituted heterocyclic ring with the boron atom, such rings having up to 7 carbon, nitrogen, oxygen, or nitrogen atoms. The optional substituents on R¹, R², R³, and R⁴ can include chloro, fluoro, nitro, alkyl, alkoxy, and acetoxy groups. In some embodiments, all the R¹, R², R³, and R⁴ are the same or different substituted or unsubstituted aryl groups such as substituted or unsubstituted phenyl groups, or more likely all of these groups are unsubstituted phenyl groups. In many embodiments, at least one of X₁, X₂, and X₃ is a tetraarylborate anion comprising the same or different aryl groups, or in particularly useful embodiments, one or more is a tetraphenylborate anion or each of X₁, X₂, and X₃ is a tetraphenylborate anion.

Mixtures of Compound B compounds represented by Structures (II) or (III) can be used if desired. Many useful compounds represented by Structures (I), (II), and (III) can be obtained from commercial sources such as Sigma-Aldrich or they can be prepared using known synthetic methods and readily available starting materials.

The molar ratio of compound A to compound B is generally from 10:90 to and including 90:10, or more likely from 20:80 to and including 80:20.

The initiator composition is generally present in the radiation-sensitive imagable layer sufficient to provide one or more polymerization initiators in an amount of at least 3 weight % and up to and including 30 weight %, or typically of at least 5 weight % and up to and including 18 weight %, or even of at least 7 weight % and up to and including 15 weight %, all based on the total weight of the radiation-sensitive imagable layer.

It is optional but desirable in many embodiments that the radiation-sensitive imagable layer further comprise a polymeric material that acts as a polymeric binder for all the materials in the noted layer. Such “polymer binders” are different from the one or more free radically polymerizable components described above, and are generally non-polymerizable and non-crosslinkable.

Such polymeric binders can be selected from a number of polymeric binder materials known in the art including polymers comprising recurring units having side chains comprising polyalkylene oxide segments such as those described in for example, U.S. Pat. No. 6,899,994 (Huang et al.) the disclosure of which is incorporated herein by reference. Other useful polymeric binders comprise two or more types of recurring units having different side chains comprising polyalkylene oxide segments as described in for example WO Publication 2015-156065 (Kamiya et al.). Some of such polymeric binders can further comprise recurring units having pendant cyano groups as those described in for example U.S. Pat. No. 7,261,998 (Hayashi et al.) the disclosure of which is incorporated herein by reference.

Some useful polymeric binders are present in particulate form, that is, in the form of discrete particles (non-agglomerated particles). Such discrete particles can have an average particle size of at least 10 nm and up to and including 1500 nm, or typically of at least 80 nm and up to and including 600 nm, and that are generally distributed uniformly within the radiation-sensitive imagable layer. Other polymeric binders can be present as particles having an average particle size of at least 50 nm and up to and including 400 nm. Average particle size can be determined by various known methods including measuring the particles in electron scanning microscope images, and averaging a set number of measurements.

In some embodiments, the polymeric binder is present in the form of particles having an average particle size that is less than the average dry thickness (t) of the radiation-sensitive imagable layer. The average dry thickness (t) in micrometers (μm) is calculated by the following Equation:

t=w/r

wherein w is the dry coating coverage of the radiation-sensitive imagable layer in g/m² and r is 1 g/cm³. For example, in such embodiments, the polymeric binder can comprise at least 0.05% and up to and including 80%, or more likely at least 10% and up to and including 50%, of the average dry thickness (t) of the radiation-sensitive imagable layer.

The polymeric binders also can have a backbone comprising multiple (at least two) urethane moieties as well as pendant groups comprising the polyalkylenes oxide segments.

Other useful polymeric binders also include those that comprise polymerizable groups such as acrylate ester group, methacrylate ester group, vinyl aryl group and allyl group and those that comprise alkali soluble groups such as carboxylic acid. Some of these useful polymeric binders are described in U.S. Patent Application Publication 2015/0099229 (Simpson et al.) and U.S. Pat. No. 6,916,595 (Fujimaki et al.), the disclosures of both of which are incorporated herein by reference.

Useful polymeric binders generally have a weight average molecular weight (Mw) of at least 2,000 and up to and including 500,000, or at least 20,000 and up to and including 300,000, as determined by Gel Permeation Chromatography (polystyrene standard).

Useful polymeric binders can be obtained from various commercial sources or they can be prepared using known procedures and starting materials, as described for example in publications described above.

When present, the total polymeric binders can be present in the radiation-sensitive imagable layer in an amount of at least 10 weight % and up to and including 70 weight %, or more likely in an amount of at least 20 weight % and up to and including 50 weight %, based on the total dry weight of the radiation-sensitive imagable layer.

Other polymeric materials known in the art can be present in the radiation-sensitive imagable layer as addenda and such polymeric materials are generally more hydrophilic than the polymeric binders described above. Example of such hydrophilic “secondary” polymeric binders include but are not limited to, cellulose derivatives such as hydroxypropyl cellulose, carboxymethyl cellulose, and polyvinyl alcohol with various degrees of saponification.

Additional additives to the radiation-sensitive imagable layer can include dye precursors and color developers as are known in the art. Useful dye precursors include but are not limited to, phthalide and fluoran leuco dyes having a lactone skeleton with an acid dissociation property, such as those described in U.S. Pat. No. 6,858,374 (Yanaka), the disclosure of which is incorporated herein by reference.

The radiation-sensitive imagable layer can include crosslinked polymer particles having an average particle size of at least 2 μm, or of at least 4 μm, and up to and including 20 μm as described for example in U.S. Ser. No. 14/642,876 (filed Mar. 10, 2015 by Hayakawa et al.) and in U.S. Pat. No. 8,383,319 (Huang et al.) and U.S. Pat. No. 8,105,751 (Endo et al), the disclosures of all of which are incorporated herein by reference. Such crosslinked polymeric particles can be present only in the radiation-sensitive imagable layer, the protective layer when present (described below), or in both the radiation-sensitive imagable layer and the protective layer when present.

The radiation-sensitive imagable layer can also include a variety of other optional addenda including but not limited to, dispersing agents, humectants, biocides, plasticizers, surfactants for coatability or other properties, viscosity builders, pH adjusters, drying agents, defoamers, preservatives, antioxidants, development aids, rheology modifiers, or combinations thereof, or any other addenda commonly used in the lithographic art, in conventional amounts. The radiation-sensitive imagable layer can also include a phosphate (meth)acrylate having a molecular weight generally greater than 250 as described in U.S. Pat. No. 7,429,445 (Munnelly et al.) the disclosure of which is incorporated herein by reference.

### Hydrophilic Protective Layer

While in some embodiments of the present invention, the radiation-sensitive imagable layer is the outermost layer with no layers disposed thereon, it is possible that the precursors can be designed with a hydrophilic protective layer (also known in the art as a hydrophilic overcoat, oxygen-barrier layer, or topcoat) disposed directly on the radiation-sensitive imagable layer (no intermediate layers between these two layers). Such precursors can be developed on-press as well as off-press using any suitable developer as described below.

When present, this hydrophilic protective layer is generally the outermost layer of the precursor and thus, when multiple precursors are stacked one on top of the other, the hydrophilic protective layer of one precursor can be in contact with the backside of the substrate of the precursor immediately above it, where no interleaving paper is present.

Such hydrophilic protective layers can comprise one or more film-forming water-soluble polymeric binders in an amount of at least 60 weight % and up to and including 100 weight %, based on the total dry weight of the hydrophilic protective layer. Such film-forming water-soluble (or hydrophilic) polymeric binders can include a modified or unmodified poly(vinyl alcohol) having a saponification degree of at least 30%, or a degree of at least 75%, or a degree of at least 90%, and a degree of up to and including 99.9%.

Further, one or more acid-modified poly(vinyl alcohol)s can be used as film-forming water-soluble (or hydrophilic) polymeric binders in the hydrophilic protective layer. For example, at least one modified poly(vinyl alcohol) can be modified with an acid group selected from the group consisting of carboxylic acid, sulfonic acid, sulfuric acid ester, phosphonic acid, and phosphoric acid ester groups. Examples of such materials include but are not limited to, sulfonic acid-modified poly(vinyl alcohol), carboxylic acid-modified poly(vinyl alcohol), and quaternary ammonium salt-modified poly(vinyl alcohol), glycol-modified poly(vinyl alcohol), or combinations thereof.

The optional hydrophilic overcoat can also include crosslinked polymer particles having an average particle size of at least 2 μm and as described for example in U.S. Ser. No. 14/642,876 (filed Mar. 10, 2015 by Hayakawa et al.) and in U.S. Pat. No. 8,383,319 (Huang et al.) U.S. Pat. No. 8,105,751 (Endo et al), the disclosures of all of which are incorporated herein by reference.

When present, the hydrophilic protective layer is provided as a hydrophilic protective layer formation and dried to provide a dry coating coverage of at least 0.1 g/m² and up to but less than 4 g/m², and typically at a dry coating coverage of at least 0.15 g/m² and up to and including 2.5 g/m². In some embodiments, the dry coating coverage is as low as 0.1 g/m² and up to and including 1.5 g/m² or at least 0.1 g/m² and up to and including 0.9 g/m², such that the hydrophilic protective layer is relatively thin for easy removal during off-press development or on-press development.

The hydrophilic protective layer can optionally comprise organic wax particles dispersed, generally uniformly, within the one or more film-forming water-soluble (or hydrophilic) polymeric binders as described for example in U.S. Patent Application Publication 2013/0323643 (Balbinot et al.) the disclosure of which is incorporated herein by reference.

### Radiation-Sensitive Lithographic Printing Plate Precursors

The radiation-sensitive lithographic printing plate precursors of the present invention can be provided in the following manner. In a first step A), a radiation-sensitive imagable layer formulation comprising materials described above can be applied to a hydrophilic surface of a suitable substrate, usually as a continuous substrate web, as described above using any suitable equipment and procedure, such as spin coating, knife coating, gravure coating, die coating, slot coating, bar coating, wire rod coating, roller coating, or extrusion hopper coating. Such formulation can also be applied by spraying onto a suitable substrate. Typically, once the radiation-sensitive imagable layer formulation is applied at a suitable wet coverage, it is dried in a suitable manner known in the art to provide a desired dry coverage as noted below, thereby providing a radiation-sensitive continuous web or a radiation-sensitive continuous article.

As noted above, before the radiation-sensitive imagable layer formulation is applied, the substrate (that is, a continuous roll or web) has been electrochemically grained and anodized as described above to provide a suitable hydrophilic anodic oxide layer on the outer surface of the aluminum-containing support, and the anodized surface usually can be post-treated with a hydrophilic polymer solution as described above. The conditions and results of these operations are well known in the art as described above in the Substrate section.

The manufacturing methods typically includes mixing the various components needed for the radiation-sensitive imagable layer chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereofj, applying the resulting radiation-sensitive imagable layer formulation to the continuous substrate web, and removing the solvent(s) by evaporation under suitable drying conditions. After proper drying, the dry coating coverage of the radiation-sensitive imagable layer on the continuous substrate web is generally at least 0.1 g/m² and up to and including 4 g/m² or at least 0.4 g/m² and up to and including 2 g/m² but other dry coverage amounts can be used if desired.

In some embodiments, the radiation-sensitive imagable layer formulation used in this method is an infrared radiation-sensitive imagable layer formulation in which the one or more radiation absorbers are one or more infrared radiation absorbers.

As described above, in some embodiments, a suitable aqueous-based hydrophilic protective layer formulation (described above) can be applied in a step B) to the dried radiation-sensitive imagable layer using known coating and drying conditions, equipment, and procedures.

In practical manufacturing conditions, the result of these coating operations is a continuous radiation-sensitive web (or roll) of radiation-sensitive lithographic printing plate precursor material having either only a radiation-sensitive imagable layer or both a radiation-sensitive imagable layer and a protective layer disposed on the continuous substrate web that also has a hydrophilic anodic oxide layer.

Individual rectangular lithographic printing plate precursors are formed from this resulting continuous radiation-sensitive web or roll by slitting and cutting-to-length (“CTL”) process that creates one or more longitudinal strips from the continuous radiation-sensitive web. This process is typically used to remove the unwanted edge regions of the continuous radiation-sensitive web and to create two or more strips, each of which has a width equal to one dimension of rectangular lithographic printing plate precursors. Thus, the cutting-to-length process is used to create a lateral cut across each strip at an interval equal to the other dimension of rectangular lithographic printing plate precursors, thereby forming individual precursors usually rectangular in shape.

Shear droop is thus created at the opposing edges within each individual precursor during the noted slitting process. The slitting condition for forming these individual precursors is not particularly restricted as long as the shear droop has the dimensions X and Y identified below and as illustrated in FIGS. 1a, 1b, 1c, and 1d.

Cutting or slitting devices designed for this purpose are well known in the art. Useful slitting devices comprise one or more sets of opposing rotary blades arranged in pairs, one rotary blade of each pair being placed above and the other rotary blade in the pair being placed below the continuous radiation-sensitive web. This arrangement is illustrated in FIG. 2 that is an exploded schematic view of a pair of overlapping rotary blades 12a and 12b arranged to provide overlapping distance “d” and clearance distance “c” for slitting. FIG. 2 also illustrates the positioning of continuous radiation-sensitive web 14. One or more sets of such overlapping rotary blades can be arranged in slitting device 16 that is illustrated in a configuration shown in FIG. 3 in which multiple pairs of overlapping rotary blades 12a and 12b are shown in position to form multiple radiation-sensitive strips 18. With slitting device 16, a desired shear droop can be created by controlling both the clearance between overlapping rotary blades 12a and 12b and the overlap distance d that one rotary blade extends over the edge of the other rotary blade (see FIG. 2).

FIG. 3 also shows the direction of movement Z for formed multiple radiation-sensitive strips 18, and the pressurized application of hydrophilic coating band formulation 20 to opposing edge 22 using microspray gun nozzle 24 and air pressure controller 26. Hydrophilic coating band formulations 20 are supplied from hydrophilic coating solution tank 34 while flow rates are monitored using flowmeters 36. Drying air 32 is directed over hydrophilic coating band 28 within drying air flow guide 30.

FIG. 1a illustrates a cross-sectional view of individual lithographic printing plate precursor 1 that can have a square or rectangular (oblong) shape or form in a top view. Thus, FIG. 1a is a cross-sectional view along one side of the square or rectangular shape, and it shows opposing edge 3, substrate 2, anodic oxide layer 4, radiation-sensitive imagable layer 5, and hydrophilic coating band 6 that is also the outermost surface of precursor 1. FIG. 1c illustrates the same structure as shown in FIG. 1a except for the absence of hydrophilic coating band 6. As noted above, alternative precursors as shown in FIG. 1b can also comprise protective layer 10 that is disposed directly on radiation-sensitive imagable layer 5 and underneath hydrophilic coating band 6. FIG. 1d illustrates the same structure as FIG. 1b except for the absence of hydrophilic coating band 6. While it is not shown in FIGS. 1a and 1b, hydrophilic coating band 6 can also extend downward and partially or wholly cover opposing edge 3.

In the cross-sectional views of FIGS. 1a, 1 b, 1c, and 1d, distance Y from the upper edge of opposing edge 3 (boundary point between shear droop 7 and opposing edge 3) to an extended line from outermost surface 8 of the radiation-sensitive imagable layer 5 in FIGS. 1a and 1c or outermost surface 8 of protective layer 10 in FIGS. 1b and 1d, is referred to as “shear droop depth”. The extended line from outermost surface 9 in FIGS. 1a, 1b, 1c, and 1d is defined as a linear function fitted to the outermost surface at least 2.0 mm away from an extended line of opposing edge 3 for at least 1.5 mm distance by a least squares method. A distance X (shear droop width) extending from a point where precursor outermost surface 8 begins to droop to an extended line of opposing edge 3 is referred to as “shear droop width”. It can be seen from these illustrations that shear droop 7 in general is evident not only in substrate 2 and anodic oxide layer 4 thereon, but also in all other layers such as radiation-sensitive imagable layer 5 and any protective layer 10. While the shear droop is usually created before the hydrophilic coating band is applied, shear droop width X and shear droop depth Y according to the present invention are to be measured after step D) described below.

According to the present invention, shear droop depth Y is generally at least 20 μm and up to and including 200 μm, or more likely at least 50 μm and up to and including 150 μm, and more specifically, at least 70 μm and up to and including 120 μm.

In addition, shear droop width X is generally at least 500 μm and up to and including 2000 μm, or more likely at least 750 μm and up to and including 1500 μm, and more specifically, at least 1000 μm and up to and including 1500 μm.

In certain embodiments, shear droop depth Y is at least 50 μm and up to and including 150 μm, and shear droop width X is at least 750 μm and up to and including 1500 μm.

To achieve the advantages of the present invention, D) is carried out to form a band of a hydrophilic coating 6 from a hydrophilic coating formulation (described below) over radiation-sensitive imagable layer 5 (in FIGS. 1a and 1b) and over any protective layer that may be disposed thereon. This coating operation is designed to extend the hydrophilic coating band 6 to the hydrophilic coating band width A (in FIGS. 1a and 1b) from each of the two opposing edges (such as opposing edge 3 in FIGS. 1a and 1b) inward along the hydrophilic surface of substrate 2 and anodic oxide layer 4 for a distance (hydrophilic coating band width A) of at least 1.5 times, or even at least 2 times, shear droop width X. In general, hydrophilic coating band 6 is disposed over the radiation-sensitive imagable layer and any protective layer disposed thereon, from each of the two opposing edges independently along the hydrophilic surface of substrate 2 and anodic oxide layer 4 (hydrophilic surface) for a hydrophilic coating band width A of at least 200 μm and up to and including 4000 μm or for a hydrophilic coating band width A of at least 750 μm and up to and including 4000 μm.

Treatment of individual precursors with the hydrophilic coating formulation can be carried out in any suitable manner with suitable equipment that allows one to form a hydrophilic coating band from a hydrophilic coating formulation inward along each of the two opposing edges showing shear droop.

For example, the hydrophilic coating formulation can be applied in a precise manner using a non-contact means such as by using one or more spray nozzles at a flow rate that suitably matches the speed of the continuous radiation-sensitive web. Alternatively, molton rollers of a desired size can be used under similar application conditions. In addition, the hydrophilic coating band can be formed using a flexographic printing member (“relief member”) on which the hydrophilic coating formulation is carried as an “ink.”

The applied hydrophilic coating band is typically dried using suitable drying means such as by blowing hot air to reduce tackiness. Drying conditions can vary from room temperature and up to and including 200° C., for a few seconds and up to several minutes depending upon the drying temperature and coverage of the hydrophilic coating formulation.

The dry coverage rate of the hydrophilic coating band at the center of the band is typically at least 0.1 g/m² and up to and including 5 g/m², or the dry thickness of the hydrophilic coating band at the center of the band is at least 0.1 μm and up to and including 5 μm. The dry thickness can be measured by SEM analytical procedures to provide cross sectional views as illustrated in FIGS. 1a and 1b. A cross section of a precursor can be created by a freeze-fracture process that involves immersing a piece of the lithographic printing plate precursor having the opposing edge of interest and then bending that opposing edge until cracks are formed in the anodic oxide layer and the overlying coatings. The dry coverage rate can be calculated from a spectroscopic signal strength measured at or near the center of the hydrophilic coating band according to the relationship between the spectroscopic signal strength and the coverage rate determined from a sample having the hydrophilic coating of the same composition as the hydrophilic coating band but applied substantially uniformly across a piece of the lithographic printing plate precursor having an area large enough for gravimetric measurement of the coverage rate. Suitable spectroscopic signals include the signal of an appropriate element in X-ray fluorescence (XRF).

Another useful technique for estimating the coverage rate is to add a small amount of visible dye into the hydrophilic coating and then measure the reflective optical density (OD) at or near the center of the hydrophilic coating band. The coverage rate can be calculated from the OD according to a suitable calibration curve established from a sample of the lithographic printing plate precursor substantially uniformly coated with a hydrophilic coating formulation of the same composition as the hydrophilic coating band.

Multiple applications of the same or different hydrophilic coating formulation can be made if desired to obtain a desired thickness or performance.

In general, the hydrophilic coating formulation is a predominantly aqueous solution, meaning that of the liquids present, at least 70 weight % and up to and including 100 weight % of total solvents is comprised of water (such as deionized water). The remaining solvents can be water-miscible organic solvents such as ethanol, methanol, n-propanol, and iso-propanol. The pH of the hydrophilic coating formulation is typically at least 3 and up to and including 9.

Its viscosity can vary depending upon the means for application, but it is generally at least 1 centipoise (0.001 Pa-sec) and up to and including 50 centipoises (0.050 Pa-sec) as measured at 25 weight % and 25° C. using a standard viscometer.

The hydrophilic coating formulation (and resulting hydrophilic coating band) has as an essential component, one or more amphoteric surfactants, that are present in the hydrophilic coating formulation such that upon drying, the resulting hydrophilic coating band comprises the one or more amphoteric surfactants in a total amount of at least 5 weight % and up to and including 90 weight %, or more likely at least 10 weight % and up to and including 80 weight %, based on the total dry weight of the hydrophilic coating band.

Mixtures of amphoteric surfactants defined herein can be used if desired, in any useful weight or molar proportion. However, the total amount of such amphoteric surfactants is greater than, on a weight basis, than the total of all other types of surfactants including anionic, cationic, and nonionic surfactants. In some embodiments, the hydrophilic coating band is essentially free of anionic, cationic, and nonionic surfactants, meaning that these types of surfactants are not intentionally added to the hydrophilic coating band formulation, and that they may be present in the hydrophilic coating band in an amount of less than 1 weight % based on the total dry weight of the hydrophilic coating band.

Useful one or more amphoteric surfactants for the purpose of the present invention are not limited to, but can be independently represented by the following Structure (V):

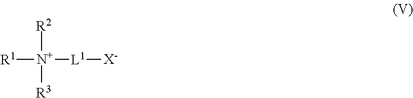

wherein R¹ represents a substituted or unsubstituted alkyl group (linear or branched) having 6 to 24 carbon atoms, or more likely a substituted or unsubstituted alkyl group (linear or branched) having 8 to 18 carbon atoms. Such substituted or unsubstituted alkyl group is directly connected to the positively-charged nitrogen atom or is indirectly connected to the positively-charged nitrogen atom through a hetero connecting group, for example through an amide linkage such as —C(═O)NR⁴-L²-.

In Structure (V), R² and R³ independently represent hydrogen or a substituted or unsubstituted alkyl group (linear or branched) having 1 to 5 carbon atoms such as substituted or unsubstituted methyl, ethyl, 2-hydroxyethyl, n-propyl, iso-propyl, and t-butyl groups, or having 1 to 3 carbon atoms.

Moreover, in the noted amide linkage, R⁴ represents hydrogen or a substituted or unsubstituted alkyl group (linear or branched) having 1 to 3 carbon atoms, such as substituted or unsubstituted methyl, ethyl, 2-hydroxyethyl, n-propyl, and iso-propyl groups. L² is a substituted or unsubstituted alkylene group (linear or branched) having 1 to 4 carbon atoms.

In Structure (I), L¹ represents a substituted or unsubstituted aliphatic linking group (linear or branched) having 1 to 4 atoms in the chain, such as a substituted or unsubstituted alkylene group for example, a substituted or unsubstituted methylene, ethylene, iso-propylene, or t-butylene group.

In many embodiments, L¹ and L² independently represent a substituted or unsubstituted alkylene group (linear or branched) having 1 to 3 carbon atoms.

X⁻ represents an anionic group or a salt thereof, such as a carboxy, carboxylate, sulfo, sulfate, phospho, or phosphate group.

Representative useful amphoteric surfactants are readily available from various commercial sources, and include but are not limited to, NISSAN ANON BDF-SF containing cocamidopropyl betaine (NOF Corporation, Japan), and the commercial products NISSAN ANON BDC-S; NISSAN ANON BDF-R, NISSAN ANON BL-SF, and NISSAN ANON BL (all NOF Corporation, Japan) containing various betaines, as well as the other commercial materials identified in Col. 16 (lines 31-51) of U.S. Pat. No. 8,771,920 (Fujii et al.), the disclosure of which is incorporated herein by reference for describing such amphoteric surfactants.

The hydrophilic coating formulation (and resulting hydrophilic coating band) also optionally include one or more hydrophilic film-forming polymers that are present in the hydrophilic coating formulation in an amount such that upon drying, the resulting hydrophilic coating band comprises the one or more hydrophilic film-forming polymers in an amount of at least 10 weight % and up to and including 90 weight %, or more likely at least 20 weight % and up to and including 80 weight %, based on the total dry weight of the hydrophilic coating band.

While the type of useful hydrophilic film-forming polymers is not particularly limited, representative useful hydrophilic film-forming polymers can be represented by either of the following Structures (Ia) and (Ib):

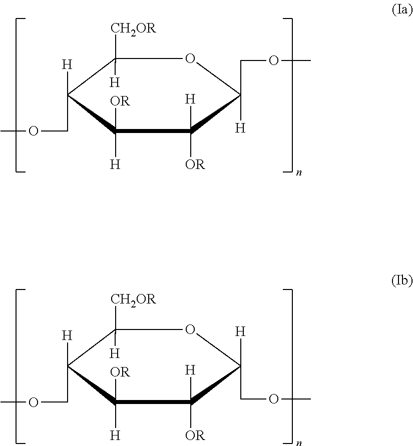

wherein R represents hydrogen; a substituted or unsubstituted alkyl group (linear or branched) having 1 to 4 carbon atoms; a —CH₂C(═O)OM group; or a —(CₘH₂ₘO)ₓH group. The three R groups can be the same or different.

M represents hydrogen or an alkali metal ion such as sodium, or potassium.

Also, m represents an integer of 2, 3, or 4, or typically, 2 or 3.

Moreover, n and x independently represent an integer of 1 or more such as at least 1 and up to and including 500,000, provided that the three R groups in Structure (Ia) or Structure (Ib) have a total substitution degree of at least 0.5 and up to and including 3, or at least 0.6 and up to and including 2.5, or even at least 1.0 and up to and including 2.5. In Structures (Ia) and (Ib), n is generally larger than x.

Representative useful hydrophilic film-forming polymers include but are not limited to, materials represented by either or both of Structures (Ia) and (Ib) noted above, such as etherified starches, hydroxyalkyl celluloses such as hydroxyethyl cellulose, hydroxypropyl cellulose, hydroxyethylmethyl cellulose, hydroxypropylmethyl cellulose, or a modified product of any of these materials, or mixtures thereof. Other useful hydrophilic film-forming polymers include but are not limited to, polyvinyl acetate (having a hydrolysis degree of at least 65%), poly(meth)acrylic acid and alkali metal or amine salts thereof, copolymers derived at least in part from (meth)acrylic acid and alkali metal or amine salts thereof, polyacrylamides (including copolymers), polyhydroxy(meth)acrylates (including copolymers), polyvinyl pyrrolidone (including copolymers), gum arabic, dextrins and derivatives thereof, vinyl methyl ether/maleic anhydride copolymers, and others that would be readily apparent to one skilled in polymer chemistry.

The hydrophilic coating formulation (and corresponding hydrophilic coating band) can include various addenda that may be useful for formulation, coating, or shelf life, including but not limited to, biocides, buffering agents, and antifoaming agents, all in amounts that would be readily apparent from routine experimentation.

In some particularly useful embodiments, the hydrophilic coating formulation comprises one or more hydrophilic film-forming polymers, each of which can be represented by Structure (Ia) or (Ib):

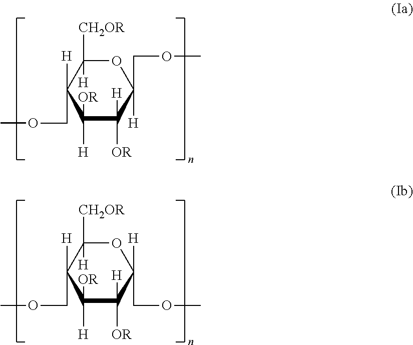

wherein R, M, n, and x are as defined above, and

an amphoteric surfactant represented by the following Structure (V):

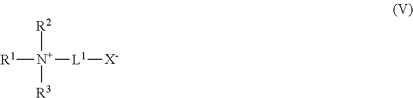

wherein R¹, R², R³, L¹, and X⁻ are defined above.

### Imaging (Exposing) Conditions

During use, a radiation-sensitive lithographic printing plate precursor of this invention can be exposed to a suitable source of exposing radiation depending upon the radiation absorber present in the radiation-sensitive imagable layer. In some embodiments where the radiation-sensitive imagable layer contains infrared radiation absorbers, the corresponding lithographic printing plate precursors can be imaged with infrared lasers that emit significant infrared radiation within the range of at least 750 nm and up to and including 1400 nm, or of at least 800 nm and up to and including 1250 nm. In other embodiments, the lithographic printing plate precursors can be imaged in the UV or visible regions of the electromagnetic spectrum using suitable sources of imaging radiation.

For example, imaging can be carried out using imaging or exposing radiation from a radiation-generating laser (or array of such lasers). Imaging also can be carried out using imaging radiation at multiple wavelengths at the same time if desired. The laser used to expose the precursor is usually a diode laser, because of the reliability and low maintenance of diode laser systems, but other lasers such as gas or solid-state lasers can also be used. The combination of power, intensity and exposure time for radiation imaging would be readily apparent to one skilled in the art.

The imaging apparatus can be configured as a flatbed recorder or as a drum recorder, with the radiation-sensitive lithographic printing plate precursor mounted to the interior or exterior cylindrical surface of the drum. An example of useful imaging apparatus is available as models of KODAK® Trendsetter platesetters (Eastman Kodak Company) and NEC AMZISetter X-series (NEC Corporation, Japan) that contain laser diodes that emit radiation at a wavelength of about 830 nm. Other suitable imaging apparatus includes the Screen PlateRite 4300 series or 8600 series platesetters (available from Screen USA, Chicago, Ill.) or thermal CTP platesetters from Panasonic Corporation (Japan) that operates at a wavelength of 810 nm.

In embodiments where an infrared radiation source is used, imaging energies can be at least 30 mJ/cm² and up to and including 500 mJ/cm² and typically at least 50 mJ/cm² and up to and including 300 mJ/cm² depending upon the sensitivity of the radiation-sensitive imagable layer.

### Processing (Development) and Printing

After imagewise exposing, the exposed radiation-sensitive lithographic printing plate precursors having exposed regions and non-exposed regions in the radiation-sensitive imagable layer are processed in a suitable manner to remove the non-exposed regions (and any hydrophilic protective layer over such regions).

Processing can be carried out off-press using any suitable developer in one or more successive applications (treatments or developing steps) of the same or different processing solution. Such one or more successive processing treatments can be carried out with exposed precursors for a time sufficient to remove the non-exposed regions of the radiation-sensitive imagable layer to reveal the hydrophilic surface of the substrate, but not long enough to remove significant amounts of the exposed regions that have been hardened in the same layer. During lithographic printing, the revealed hydrophilic substrate surface repels inks while the remaining exposed regions accept lithographic printing ink.

Prior to such off-press processing, the exposed precursors can be subjected to a “pre-heating” process to further harden the exposed regions in the radiation-sensitive imagable layer. Such optional pre-heating can be carried out using any known process and equipment generally at a temperature of at least 60° C. and up to and including 180° C.

Following this optional pre-heating, or in place of the pre-heating, the exposed precursor can be washed (rinsed) to remove any hydrophilic protective layer that is present. Such optional washing (or rinsing) can be carried out using any suitable aqueous solution (such as water or an aqueous solution of a surfactant) at a suitable temperature and for a suitable time that would be readily apparent to one skilled in the art.

Useful developers can be ordinary water or can be formulated aqueous solutions. The formulated developers can comprise one or more components selected from surfactants, organic solvents, alkali agents, and surface protective agents. For example, useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol.

Examples of useful developers for carrying out the present invention are available as TN-D1 (Kodak Japan Ltd.), TN-D2 (Kodak Japan Ltd.), and HN-D (FUJIFILM Global Graphic Systems Co, Ltd.). All of these developers are provided in concentrated form, and can be used when diluted with water at specified dilution ratios.

Following development, the exposed and developed precursor can be washed (rinsed) to remove residual developer solution, and then can be treated with a gumming solution that is capable of protecting (or “gumming”) the lithographic image on the lithographic printing plate against contamination or damage (for example, from oxidation, fingerprints, dust, or scratches).

Examples of useful gumming solutions are available as LNF-11 (Kodak Japan Ltd.), LNF-12 (Kodak Japan Ltd.) and HN-GV (FUJIFILM Global Graphic Systems Co, Ltd.). All of these gumming solutions are provided in concentrated form and can be used when diluted with water at specified dilution ratios.

In some instances, an aqueous processing solution can be used off-press to both develop the imaged precursor by removing the non-exposed regions and also to provide a protective layer or coating over the entire imaged and developed (processed) precursor printing surface. In this embodiment, the aqueous alkaline solution behaves somewhat like a gum that is capable of protecting (or “gumming”) the lithographic image on the printing plate against contamination or damage (for example, from oxidation, fingerprints, dust, or scratches).

After the described off-press processing and optional drying, the resulting lithographic printing plate can be mounted onto a printing press without any contact with additional solutions or liquids. It is optional to further bake the lithographic printing plate with or without blanket or floodwise exposure to UV or visible radiation.

After off-press developing, printing can be carried out by putting the exposed and processed lithographic printing plate on a suitable printing press, and applying a lithographic printing ink and fountain solution to the printing surface of the lithographic printing plate in a suitable manner. The fountain solution is taken up by the surface of the hydrophilic substrate revealed by the exposing and processing steps, and the lithographic ink is taken up by the remaining (exposed) regions of the imagable layer. The lithographic ink is then transferred to a suitable receiving material (such as cloth, paper, metal, glass, or plastic) to provide a desired impression of the image thereon. If desired, an intermediate “blanket” roller can be used to transfer the lithographic ink from the lithographic printing plate to the receiving material (for example, sheets of paper).

On-Press Development and Printing:

Alternatively, the lithographic printing plate precursors according to the present invention are on-press developable using a lithographic printing ink, a fountain solution, or a combination of a lithographic printing ink and a fountain solution. In such embodiments, an imaged radiation-sensitive lithographic printing plate precursor according to the present invention is mounted onto a printing press and the printing operation is begun. The non-exposed regions in the radiation-sensitive imagable layer are removed by a suitable fountain solution, lithographic printing ink, or a combination of both, when the initial printed impressions are made. Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Varn International, Addison, Ill.).

In a typical printing press startup with a sheet-fed printing machine, the dampening roller is engaged first and supplies fountain solution to the mounted imaged precursor to swell the exposed radiation-sensitive imagable layer at least in the non-exposed regions. After a few revolutions, the inking rollers are engaged and they supply lithographic printing ink(s) to cover the entire printing surface of the lithographic printing plates. Typically, within 5 to 20 revolutions after the inking roller engagement, printing sheets are supplied to remove the non-exposed regions of the radiation-sensitive imagable layer from the lithographic printing plate as well as materials on a blanket cylinder if present, using the formed ink-fountain emulsion.

On-press developability of the lithographic printing precursors is particularly useful when the precursor comprises one or more polymeric binders in the radiation-sensitive imagable layer, at least one of which polymeric binders is present as particles having an average diameter of at least 50 nm and up to and including 400 nm.

The present invention provides at least the following embodiments and combinations thereof, but other combinations of features are considered to be within the present invention as a skilled artisan would appreciate from the teaching of this disclosure:

1. A lithographic printing plate precursor comprising:

a substrate comprising a hydrophilic surface and two opposing edges having edge surfaces;

a radiation-sensitive imagable layer that is disposed on the hydrophilic surface of the substrate, the radiation-sensitive imagable layer comprising:
one or more free radically polymerizable components, an initiator composition that provides free radicals upon exposure of the radiation-sensitive imagable layer to radiation,
one or more radiation absorbers, and
optionally, a polymeric binder different from the one or more free radically polymerizable components;

wherein the lithographic printing plate precursor has a shear droop at each of the two opposing edges, which shear droop has a shear droop depth Y of at least 20 μm and up to and including 200 μm, and a shear droop width X of at least 500 m and up to and including 2000 μm, and

wherein the lithographic printing plate precursor further comprises a band of a hydrophilic coating disposed over the radiation-sensitive imagable layer and any protective layer disposed thereon, which hydrophilic coating band extends from each of the two opposing edges inwardly along the hydrophilic surface independently for a hydrophilic coating band width A of at least 1.5 times the shear droop width X, wherein the hydrophilic coating band comprises one or more amphoteric surfactants in a total amount of at least 5 weight % and up to and including 90 weight %, based on the total dry weight of the hydrophilic coating band, which total amount of one or more amphoteric surfactants is greater than the total of all cationic, anionic, and nonionic surfactants in the hydrophilic coating band,

and the lithographic printing plate precursor optionally comprises a protective layer disposed over the radiation-sensitive imagable layer.

2. The lithographic printing plate precursor of embodiment 1, wherein the shear droop has a shear droop depth Y of at least 50 μm and up to and including 150 μm, and a shear droop width X of at least 750 μm and up to and including 1500 μm.

3. The lithographic printing plate precursor of embodiment 1 or 2, wherein the hydrophilic coating band is disposed over the radiation-sensitive imagable layer and any protective layer disposed thereon, from each of the two opposing edges inwardly along the hydrophilic surface independently for a distance A of at least 200 μm and up to and including 4,000 μm.

4. The lithographic printing plate precursor of any of embodiments 1 to 3, wherein the hydrophilic coating band further comprises one or more hydrophilic film-forming polymers in an amount of at least 10 weight %, based on the total dry weight of the hydrophilic coating band.

5. The lithographic printing plate precursor of any of embodiments 1 to 4, wherein the hydrophilic coating band further comprises one or more hydrophilic film-forming polymers, each of which is represented by either of the following Structure (Ia) or Structure (Ib):

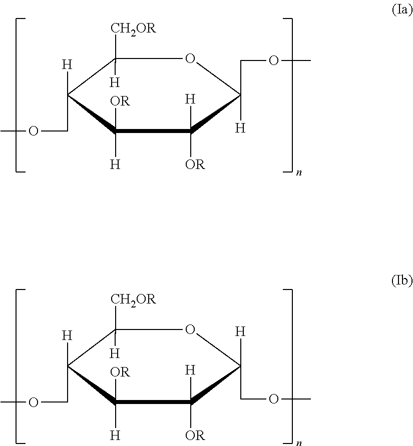

wherein R represents hydrogen, an alkyl group having 1 to 4 carbon atoms, a —CH₂C(═O)OM group, or a —(CₘH₂ₘO)ₓH group; M represents hydrogen or an alkali metal ion; m represents an integer of from 2, 3, or 4; n and x independently represent an integer of 1 or more; provided that the three R groups in Structure (Ia) or (Ib) have a total substitution degree of from 0.5 and up to and including 3.

6. The lithographic printing plate precursor of any of embodiments 1 to 5, wherein the one or more amphoteric surfactants are independently represented by the following Structure (V):

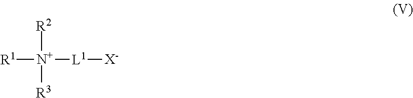

wherein R¹ represents a substituted or unsubstituted alkyl group having 6 to 24 carbon atoms, which substituted or unsubstituted alkyl group is directly connected to the positive-charged nitrogen atom or is indirectly connected to the positively-charged nitrogen atom through a hetero connecting group; R² and R³ independently represent hydrogen or a substituted or unsubstituted alkyl group having 1 to 5 carbon atoms; L¹ represents a substituted or unsubstituted aliphatic linking group having 1 to 4 atoms in the chain; and X⁻ represents an anionic group or a salt thereof.

7. The lithographic printing plate precursor of embodiment 6, wherein R¹ is a substituted or unsubstituted alkyl group having 8 to 18 carbon atoms and is connected to the nitrogen atom through an amide linkage —C(═O)NR⁴-L²-; R², R³, and R⁴ independently represent hydrogen or a substituted or unsubstituted alkyl group having 1 to 3 carbon atoms; L¹ and L² independently represent a substituted or unsubstituted alkylene group having 1 to 3 carbon atoms; and X⁻ represents a carboxy, carboxylate, sulfo, sulfate, phospho, or phosphate group.

8. The lithographic printing plate precursor of any of embodiments 1 to 8 that is on-press developable using a lithographic printing ink, a fountain solution, or a combination of a lithographic printing ink and a fountain solution.

9. The lithographic printing plate precursor of any of embodiments 1 to 8 that is rectangular in shape.

10. The lithographic printing plate precursor of any of embodiments 1 to 9, wherein the radiation-sensitive imagable layer comprises two or more free radically polymerizable components.

11. The lithographic printing plate precursor of any of embodiments 1 to 10, wherein the radiation-sensitive imagable layer comprises one or more polymeric binders, at least one of which polymeric binders is present as particles having an average particle size of at least 50 nm and up to and including 400 nm.

12. The lithographic printing plate precursor of any of embodiments 1 to 11, further comprising crosslinked polymeric particles having an average diameter of at least 2 μm, which crosslinked polymeric particles are present either in the radiation-sensitive imagable layer, the protective layer when present, or in both the radiation-sensitive imagable layer and the protective layer when present.

13. The lithographic printing plate precursor of any of embodiments 1 to 12, wherein the radiation-sensitive imagable layer is an infrared radiation-sensitive imagable layer, and the one or more radiation absorbers are one or more infrared radiation absorbers.

14. The lithographic printing plate precursor of any of embodiments 1 to 13, wherein the substrate comprises an anodic oxide layer underneath the radiation-sensitive imagable layer.

15. A method for forming a lithographic printing plate, comprising:

A) imagewise exposing a lithographic printing plate precursor according to any of embodiments 1 to 14 with radiation, to provide imagewise exposed regions and non-imagewise exposed regions in the radiation-sensitive imagable layer; and

B) removing the non-imagewise exposed regions of the radiation-sensitive imagable layer.

16. The method of embodiment 15, wherein the lithographic printing plate precursor comprises one or more polymeric binders in the radiation-sensitive imagable layer, at least one of which polymeric binders is present as particles having an average diameter of at least 50 nm and up to and including 400 nm, and

B) removing the non-imagewise exposed regions of the radiation-sensitive imagable layer is carried out on-press using a lithographic printing ink, a fountain solution, or a combination of a lithographic printing ink and a fountain solution.

17. The method of embodiment 15 or 16, wherein the imagewise exposing radiation is infrared radiation.

18. A method of preparing one or more lithographic printing plate precursors of any of embodiments 1 to 14, the method comprising:

A) applying a radiation-sensitive imagable layer formulation to a hydrophilic surface of a continuous substrate web having a longitudinal dimension along the continuous substrate web and a lateral dimension across in the continuous substrate web, the radiation-sensitive imagable layer formulation comprising:
one or more free radically polymerizable components, an initiator composition that provides free radicals upon exposure of the radiation-sensitive imagable-layer to radiation,
one or more radiation absorbers, and
optionally, a polymeric binder different from the one or more free radically polymerizable components,
to form a continuous radiation-sensitive web having a radiation-sensitive imagable layer disposed on the hydrophilic surface of the continuous substrate web;

B) optionally applying a protective layer formulation over the radiation-sensitive imagable layer to form a protective layer thereon;

C) cutting the continuous radiation-sensitive web in direction of the longitudinal dimension to form one or more radiation-sensitive strips, each of which is narrower than the width of the continuous radiation-sensitive web and has two opposing edges where cutting has occurred, and each opposing edge having a shear droop having a shear droop depth Y of at least 20 μm and up to and including 200 m, and a shear droop width X of at least 500 μm and up to and including 2000 μm;

D) forming a band of a hydrophilic coating from a hydrophilic coating formulation over the radiation-sensitive imagable layer and any protective layer disposed thereon, such that the hydrophilic coating band extends from each of the two opposing edges inwardly along the hydrophilic surface for a hydrophilic coating band width A to be at least 1.5 times the shear droop width X,
wherein the hydrophilic coating formulation comprises one or more amphoteric surfactants in a total amount of at least 5 weight % and up to and including 90 weight %, based on the total dry weight of the hydrophilic coating band, which total amount of one or more amphoteric surfactants is greater than the total of all cationic, anionic, and nonionic surfactants in the hydrophilic coating band; and

E) cutting the one or more radiation-sensitive strips in direction of the lateral dimension into one or more individual radiation-sensitive lithographic printing plates precursors.

19. The method of embodiment 18, wherein only features A), C), D), and E) are practiced.

The following Examples are provided to illustrate the practice of this invention and are not meant to be limiting in any manner. Unless otherwise indicated, the materials used in the working examples were obtained from various commercial sources.

### Invention Examples 1-2 and Comparative Examples 1-5

Preparation of Lithographic Printing Plate Precursors:

A continuous web of electrochemically grained aluminum-containing substrate was prepared by anodizing a continuous web of aluminum support with phosphoric acid under standard manufacturing conditions to provide an anodic oxide layer thickness of 500 nm. The resulting anodized aluminum-containing web was then post-treated with a poly(acrylic acid) aqueous solution to cover its anodic oxide surface layer with a dry coating weight of 0.03 g/m² of poly(acrylic acid).

The resulting continuous substrate web was coated with a negative-working radiation-sensitive imagable layer formulation (that was infrared radiation-sensitive) having the components shown as follows and dried at 110° C. for 40 seconds to provide a continuous infrared radiation-sensitive web from which individual lithographic printing plate precursors were obtained as described below. The dry imagable layer coating weight on the sensitized web was 0.9 g/m².

| Imageable Layer Component | Formulation Weight % |
|---|---|
| 1-Propanol | 39.75 |
| 2-Butanone | 40.00 |
| γ-Butyrolactone | 0.88 |
| Water | 8.60 |
| Polymer emulsion A ¹⁾ | 6.95 |
| KLUCEL ® E ²⁾ | 0.25 |
| Urethane acrylate ³⁾ | 1.65 |
| Sartomer SR399 ⁴⁾ | 0.77 |
| Iodonium, bis[4-(1- | 0.30 |
| methylethyl)phenyl]-, | |
| tetraphenylborate(1-) (1:1) | |
| Radiation absorber A | 0.15 |
| 3-Mercapto-1,2,4-triazole | 0.05 |
| BYK ® 336 ⁵⁾ | 0.18 |
| Techpolymer SSX-105 ⁶⁾ | 0.47 |
| Total | 100 |

¹⁾ Particulate primary polymeric binder emulsion prepared from a monomer mixture of polyethylene glycol methyl ether methacrylate/acrylonitrile/styrene at 10/70/20 weight % (24% by mass solution in 1-propanol/water at 76/24 weight % mix solvent, average particle size was 250 nm).
²⁾ Hydroxypropyl cellulose (Hercules Inc.).
³⁾ In a 2-butanone solution at a concentration of 80% by mass of a polymerizable compound obtained by reacting DESMODUR ® N100 with hydroxyethyl acrylate and pentaerythritol triacrylate at a 1:1.5:1.5 molar ratio.
⁴⁾ Dipentaerythritol pentaacrylate ester (Sartomer Company).
⁵⁾ Xylene/methoxypropyl acetate solution with a concentration of 25% by mass of a modified polydimethylsiloxane copolymer (BYK Additives and Instruments).
⁶⁾ Crosslinked acrylic beads, average particle size of 5.0 μm (Sekisui Plastics Co., Ltd.).
Radiation absorber A:

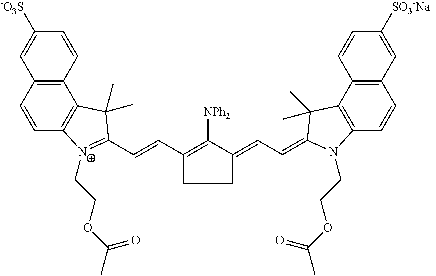

Slitting, Edge Trimming, and Application of Hydrophilic Coating Solution:

The continuous infrared radiation-sensitive web described above was slit into two strips of equal width while having the outermost edges and center portions simultaneously trimmed using four sets of rotary blades configured according to FIG. 3. The newly formed edges of these strips have a shear droop as illustrated in FIG. 1a with the droop width X shown in TABLE I.

Each outermost edge of each of the two strips was then coated with either hydrophilic coating formulation A, B, or C (described in the following table of components) to form a hydrophilic coating band that extended from the cut outermost edge inward over the dry infrared radiation-sensitive imagable layer through the shear droop region to a width A (as illustrated in FIG. 1a) of about 2 mm, and then dried with warm dry air until the hydrophilic coating band had solidified. The choice of hydrophilic coating formulation A or B is indicated below by the terms “Solution A” and “Solution B” in the “Desensitizer Solution” row of TABLE I, respectively. The formulations were applied using a spray nozzle type or molton roller type coater for Invention Examples 1-2 and Comparative Examples 1-4 as indicated in the “Applicator” row of TABLE I. A typical microspray gun nozzle type coater is illustrated in FIG. 3. Each hydrophilic band coating formulation was applied at a rate of 0.8 ml/min while the outermost edges were moving past at 45 m/min. The relative coverage of dry hydrophilic band coating was determined by XRF analysis of phosphorus. In order to evaluate the edge stain and edge scumming properties, each resulting lithographic printing plate precursor was imaged with laser scanning exposure at 120 mJ/cm² on a Screen PlateRite 4300 platesetter after aging at 40° C. and 80% RH for 8 hours.

| Hydrophilic Band Coating | Hydrophilic Coating | Hydrophilic Coating |
|---|---|---|
| Formulation Component | Formulation A | Formulation B |
| Deionized water | 75.00 | 75.00 |
| Penon JE66 ⁷⁾ | 12.95 | 12.95 |
| NISSAN ANON BDF-SF ⁸⁾ | 9.50 | 0 |
| NISSAN CATION AB-600 ⁹⁾ | 0 | 9.50 |
| Sodium hexametaphosphate | 2.50 | 2.50 |
| Bioden ZNS ¹⁰⁾ | 0.05 | 0.05 |
| Total | 100 | 100 |

⁷⁾ Etherified starch (Nippon Starch Chemical Co., Ltd.).
⁸⁾ Cocamidopropyl betaine (NOF Co.).
⁹⁾ Octadecyltrimethylammonium chloride (NOF Co.).
¹⁰⁾ Antiseptic or biocide (Daiwa Chemical Industries Co., Ltd.).

### Comparative Examples 6-7

Preparation of Lithographic Printing Plate Precursors:

A continuous web of electrochemically grained aluminum-containing substrate was prepared by anodizing a continuous web of aluminum support with phosphoric acid under standard manufacturing conditions to provide an anodic oxide layer thickness of 500 nm. The resulting anodized aluminum-containing web was then post-treated with a poly(acrylic acid) aqueous solution to cover its anodic oxide surface layer with a dry coating weight of 0.03 g/m² of poly(acrylic acid).

The resulting continuous substrate web was coated with a negative-working radiation-sensitive imagable layer formulation (that was infrared radiation-sensitive) having the components shown as follows and dried at 110° C. for 40 seconds to provide a continuous infrared radiation-sensitive web from which individual lithographic printing plate precursors were obtained as described below. The dry imagable layer coating weight on the sensitized web was 0.9 g/m².

| Imageable Layer Component | Formulation Weight % |
|---|---|
| 1-Propanol | 39.75 |
| 2-Butanone | 40.00 |
| γ-Butyrolactone | 0.88 |
| Water | 8.60 |
| Polymer emulsion A | 6.95 |
| KLUCEL ® E | 0.25 |
| Urethane acrylate | 1.65 |
| Sartomer SR399 | 0.77 |
| Iodonium, bis[4-(1- | 0.30 |
| methylethyl)phenyl]-, | |
| tetraphenylborate(1-) (1:1) | |
| Radiation absorber A | 0.15 |
| 3-Mercapto-1,2,4-triazole | 0.05 |
| BYK ® 336 | 0.18 |
| Techpolymer SSX-105 | 0.47 |
| Total | 100 |

Slitting and Edge Trimming:

The continuous infrared radiation-sensitive web described above was slit into two strips of equal width while having the outermost edges and center portions simultaneously trimmed using four sets of rotary blades configured according to FIG. 3. The newly formed edges of these strips have a shear droop as illustrated in FIG. 1c with the droop width X shown in TABLE I.

In order to evaluate the edge stain and edge scumming properties, each resulting lithographic printing plate precursor was imaged with laser scanning exposure at 120 mJ/cm² on a Screen PlateRite 4300 platesetter after aging at 40° C. and 80% RH for 8 hours.

### Invention Examples 3-4 and Comparative Examples 8-12 and 15

A continuous infrared radiation-sensitive web was prepared by applying the infrared radiation-sensitive imagable layer formulation shown below onto a continuous substrate web of electrically-grained aluminum-containing substrate prepared by anodizing with sulfuric acid under standard manufacturing condition. The imagable layer formulation was dried at 110° C. for 40 second to provide an infrared radiation-sensitive imagable layer having a dry coating weight of 1.30 g/m².

| Imageable Layer Formulation | Fomulation |
|---|---|
| Component | Weight % |
| PGME ¹¹⁾ | 30.689 |
| MEK ¹²⁾ | 59.714 |
| ACA 230AA ¹³⁾ | 5.838 |
| Radiation absorber B ¹⁴⁾ | 0.187 |
| DPHA ¹⁵⁾ | 2.849 |
| Dye B ¹⁶⁾ | 0.264 |
| MDP ¹⁷⁾ | 0.075 |
| TAZ-104 ¹⁸⁾ | 0.155 |
| P3B ¹⁹⁾ | 0.096 |
| DH-2002 ²⁰⁾ | 0.132 |
| Total | 100.000 |

¹¹⁾ Propylene glycol mono methyl ether (Tokyo Chemical Industries Co, Ltd.).
¹²⁾ 2-butanone (Tokyo Chemical Industries Co, Ltd.).
¹³⁾ Methyl methacrylate polymer with COOH group in its side chain, partially modified with 3,4-Epoxy-Cyclohexylmethyl-acrylate (Daicel Cytec Company Ltd.).
¹⁴⁾ Cyanine dye with chemical structure shown as follows:

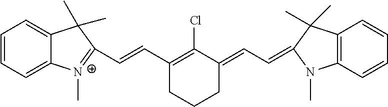 [SMILES: CN1/C(=C/C=C2\CCCC(/C=C/C3=[N+](C)c4ccccc4C3(C)C)=C2Cl)C(C)(C)c2ccccc21]

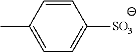

¹⁵⁾ Dipentaerythritol hexaacrylate (Nippon Kayaku Co.).
¹⁶⁾ Blue color triarylmethane type dye shown as follows: 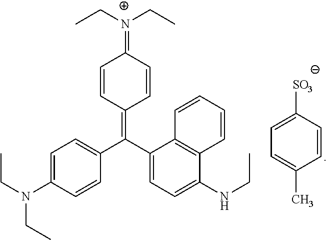
¹⁷⁾ Hindered phenol type inhibitor (Sumitomo Chemical Co., Ltd.).
¹⁸⁾ 2-(Methoxypheny1)-4,6-bis(trichloromethyl)-s-triazine (Midori chemical co, Ltd.).
¹⁹⁾ Tetra-n-butylammonium n-butyl triphenyl borate (Showa Denko K.K.).
²⁰⁾ Fluorinated polymer 25% MIBK solution (Shin-nakamura Chemical Industries Co., Ltd) of the following basic structure:

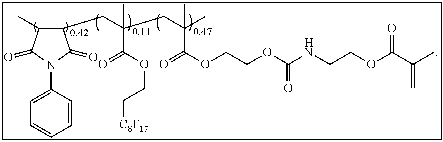

The dried infrared radiation-sensitive imagable layer was overcoated with a hydrophilic protective layer formulation having the following components and dried at 110° C. for 40 seconds. The coating weight of the dry protective layer was 0.58 g/m².

| Protective Layer | |
|---|---|
| Formulation Component | Weight % |
| Deionized water | 97.600 |
| PVA-203 ²¹⁾ | 1.882 |
| W-735 ²²⁾ | 0.209 |
| Newcol 2305 ²³⁾ | 0.069 |
| Newcol 2320 ²⁴⁾ | 0.140 |
| Techpolymer SSX-105 ²⁵⁾ | 0.100 |
| Total | 100.000 |

²¹⁾ Poly(vinyl alcohol) with saponification value of 88%, n = 3 (Kuraray).
²²⁾ Poly(vinyl pyrrolidone-co-vinyl acetate) (Ashland Inc.).
^{23), 24)} Nonionic surfactants (Nihon Nyukazai Co. Inc.).
²⁵⁾ Crosslinked acrylic beads having a 5.0 μm average diameter (Sekisui Plastics Co., Inc.).

Individual precursors from the resulting continuous infrared radiation-sensitive web were prepared by slitting, edge trimming, and application of hydrophilic coating formulation D, E, F, or G shown below using the same process as described above for Invention Example 1 (with precursor opposing edge illustrated in FIG. 1b). The choice of hydrophilic coating formulation is indicated in the “Desensitizing Solution” row of TABLES I through III. In order to evaluate the edge stain and edge scumming properties, each individual precursor was imaged with laser scanning exposure at 90 mJ/cm² on the Screen PlateRite 4300 platesetter after aging at 40° C. and 80% RH for 8 hours. After the imaging, the precursors were developed at 30° C. for 15 seconds to remove non-exposed regions of the infrared radiation-sensitive imagable layer, rinsed with water, and processed with gumming solution in a PK-1310 News processor (Kodak Japan Ltd.). For development, diluted TN-D2 developer concentrate (at a TN-D2 to water volume ratio of 1:3.5) was used. Gumming of the developed precursors was carried out using diluted LNF-11 gumming solution (at a LNF-11 to water volume ratio of 1:1).

| | Hydrophilic Coating | Hydrophilic Coating |
|---|---|---|
| Hydrophilic Coating | Formulation C | Formulation D |
| Formulation Component | (weight %) | (weight %) |
| Deionized water | 75.000 | 87.525 |
| Penon JE66⁷⁾ | 21.450 | 0 |
| Polymer C ²⁶⁾ | 0 | 7.500 |
| Sodium hexametaphosphate | 2.500 | 2.500 |
| NISSAN ANON BDF-SF ²⁷⁾ | 1.000 | 1.750 |
| Bioden ZNS ²⁹⁾ | 0.050 | 0.025 |
| KOH | 0 | 0.700 |
| Total | 100.000 | 100.000 |
| | Hydrophilic Coating | Hydrophilic Coating |
| Hydrophilic Coating | Formulation E | Formulation F |
| Formulation Component | (weight %) | (weight %) |
| Deionized water | 87.525 | 87.525 |
| Polymer C ²⁶⁾ | 7.500 | 8.750 |
| Sodium hexametaphosphate | 2.500 | 2.500 |
| NISSAN ANON BDF-SF ²⁷⁾ | 0 | 0.500 |
| Pelex NBL ²⁸⁾ | 1.750 | 0 |
| Bioden ZNS ²⁹⁾ | 0.025 | 0.025 |
| KOH | 0.700 | 0.700 |
| Total | 100.000 | 100.000 |

| | Hydrophilic Coating |
|---|---|
| Hydrophilic Coating | Formulation G |
| Formulation Component | (weight %) |
| Deionized water | 87.525 |
| Polymer C ²⁶⁾ | 7.500 |
| Sodium hexametaphosphate | 2.500 |
| NISSAN ANON BDF-SF ²⁷⁾ | 0.250 |
| Pelex NBL ²⁸⁾ | 1.500 |
| Bioden ZNS ²⁹⁾ | 0.025 |
| KOH | 0.700 |
| Total | 100.000 |

²⁶⁾ Copolymer derived from acrylamide (10 mol %), vinyl phosphoric acid (89 mol %), and methacrylamide (1 mol %).
²⁷⁾ Cocamidopropyl betaine (NOF Co.).
²⁸⁾ Butyl naphthalenesulfonic acid sodium salt aqueous solution (Kao Co.).
²⁹⁾ Antimicrobial.

The following TABLES show the components and amounts in the dried hydrophilic band coatings obtained using the Hydrophilic Coating Formulations A-G noted above.

| | Hydro- | Hydro- | Hydro- |
|---|---|---|---|
| | philic | philic | philic |
| Hydrophilic Band | Coating | Coating | Coating |
| Coating Formulation | Formu- | Formu- | Formu- |
| Component | lation A | lation B | lation C |
| Penon JE66⁷⁾ | 51.80% | 51.80% | 85.80% |
| NISSAN ANON BDF-SF⁸⁾ | 38.00% | 0.00% | 4.00% |
| NISSAN CATION AB-600⁹⁾ | 0.00% | 38.00% | 0.00% |
| Sodium hexametaphosphate | 10.00% | 10.00% | 10.00% |
| Bioden ZNS¹⁰⁾ | 0.20% | 0.20% | 0.20% |
| Total | 100% | 100% | 100% |

| | Hydro- | Hydro- | Hydro- | Hydro- |
|---|---|---|---|---|
| | philic | philic | philic | philic |
| Hydrophilic Band | Coating | Coating | Coating | Coating |
| Coating Formulation | Formu- | Formu- | Formu- | Formu- |
| Component | lation D | lation E | lation F | lation G |
| Polymer C²⁶⁾ | 60.12% | 60.12% | 70.14% | 60.12% |
| Sodium hexametaphosphate | 20.04% | 20.04% | 20.04% | 20.04% |
| NISSAN ANON BDF-SF²⁷⁾ | 14.03% | 0.00% | 4.01% | 2.00% |
| Pelex NBL²⁸⁾ | 0.00% | 14.03% | 0.00% | 12.02% |
| Bioden ZNS²⁹⁾ | 0.20% | 0.20% | 0.20% | 0.20% |
| KOH | 5.61% | 5.61% | 5.61% | 5.61% |
| Total | 100% | 100% | 100% | 100% |

### Comparative Examples 13 and 14

A continuous infrared radiation-sensitive web was prepared by applying the infrared radiation-sensitive imagable layer formulation shown below onto a continuous substrate web of electrically-grained aluminum-containing substrate prepared by anodizing with sulfuric acid under standard manufacturing condition. The imagable layer formulation was dried at 110° C. for 40 second to provide an infrared radiation-sensitive imagable layer having a dry coating weight of 1.30 g/m².

| Imageable Layer | Fomulation |
|---|---|
| Formulation Component | Weight % |
| PGME | 30.689 |
| MEK | 59.714 |
| ACA 230AA | 5.838 |
| Radiation absorber B | 0.187 |
| DPHA | 2.849 |
| Dye B | 0.264 |
| MDP | 0.075 |
| TAZ-104 | 0.155 |
| P3B | 0.096 |
| DH-2002 | 0.132 |
| Total | 100.000 |

The dried infrared radiation-sensitive imagable layer was overcoated with a hydrophilic protective layer formulation having the following components and dried at 110° C. for 40 seconds. The coating weight of the dry protective layer was 0.58 g/m².

| Protective Layer | |
|---|---|
| Formulation Component | Weight % |
| Deionized water | 97.600 |
| PVA-203 | 1.882 |
| W-735 | 0.209 |
| Newcol 2305 | 0.069 |
| Newcol 2320 | 0.140 |
| Techpolymer SSX-105 | 0.100 |
| Total | 100.000 |

Individual precursors from the resulting continuous infrared radiation-sensitive web were prepared by slitting and edge trimming using the same process as described above for Invention Example 3 (with precursor opposing edge illustrated in FIG. 1d). In order to evaluate the edge stain and edge scumming properties, each individual precursor was imaged with laser scanning exposure at 90 mJ/cm² on the Screen PlateRite 4300 platesetter after aging at 40° C. and 80% RH for 8 hours. After the imaging, the precursors were processed to remove non-exposed regions of the infrared radiation-sensitive imagable layer, rinsed, and gummed with a gumming solution to protect the precursor surface. Processing was carried out using the same apparatus and developer concentrate and gumming concentrate solutions described for Invention Examples 3-4 and Comparative Examples 7-10, noted above.

Evaluation of Precursors with Hydrophilic Band Coatings:

Edge Stain and Edge Scumming Properties:

Each of the printing plate precursors was imaged and processed as noted above to make a lithographic printing plate. Each lithographic printing plate was tested on a Roland 200 printing press (Man Roland Japan, Saitama Toda, Japan) that was run at 9,000 rpm, using a mixture 1% isopropanol and 1% NA-108W (DIC, Tokyo) in water as fountain solution, a blanket of S-7400 from (Kinyo-sha Tokyo), OK topcoat paper matte N grade paper (Oji Paper, Tokyo) as printing paper (materials), and Fusion G Magenta N grade ink (DIC, Tokyo) as lithographic printing ink. The printing paper was wider than the lithographic printing plates. The water setting was 40%. After printing 1000 copies, the printed sheets were visually inspected for the presence of unwanted ink lines at or near the edges of the lithographic printing plate. If present, the unwanted ink lines were examined under a microscope to check the presence of edge stain, edge scumming, or both of edge stain and edge scumming in the unwanted ink lines. Edge stain was considered present when the ink lines contained a relative sharp and continuous line. Edge scumming was considered present when the unwanted ink lines contained clustered ink spots with fuzzy boundaries. The presence of edge stain, edge scumming, or both of edge stain and edge scumming was further verified by examining the printing plate edges under a microscope. Edge stain was considered present when lithographic printing ink was present on the outermost edge of the shear droop. Edge scumming was considered present when the lithographic printing ink was present on the curved surface of the shear droop. Both the edge stain and edge scumming were rated as follows according to their severity.

A: No edge scumming or edge stain

B: Light edge scumming or edge stain

C: Severe edge stain or edge scumming.

The various evaluations of various precursors are presented in the following TABLES I through III.

TABLE I

| | Sample No. | | | | | | | |
|---|---|---|---|---|---|---|---|---|
| | Invention | Invention | Comparative | Comparative | Comparative | Comparative | Comparative | Comparative |
| | Example 1 | Example 2 | Example 1 | Example 2 | Example 3 | Example 4 | Example 5 | Example 6 |
| Desensitizing Solution | Solution A | Solution A | Solution B | Solution A | Solution A | Solution A | Solution C | None |
| Droop Depth Y (μm) | 30 | 150 | 30 | 10 | 300 | 30 | 30 | 30 |
| Droop Width X (μm) | 1200 | 2000 | 1200 | 400 | 2300 | 1200 | 1200 | 1200 |
| Hydrophilic Coating | 2000 | 3000 | 2000 | 2000 | 3500 | 1000 | 2000 | 2000 |
| Band Width A (μm) | | | | | | | | |
| Edge Stain Property | A | A | A | C | A | A | A | A |
| Edge Scumming | A | A | B | A | B | B | B | C |
| Property | | | | | | | | |

TABLE II

| | Sample No. | | | | | | | |
|---|---|---|---|---|---|---|---|---|
| | Invention | Invention | Comparative | Comparative | Comparative | Comparative | Comparative | Comparative |
| | Example 3 | Example 4 | Example 7 | Example 8 | Example 9 | Example 10 | Example 11 | Example 12 |
| Desensitizing Solution | Solution D | Solution D | None | Solution E | Solution D | Solution D | Solution D | Solution F |
| Droop Depth Y (μm) | 30 | 150 | 10 | 30 | 10 | 300 | 30 | 30 |
| Droop Width X (μm) | 1200 | 2000 | 400 | 1200 | 400 | 2300 | 1200 | 1200 |
| Hydrophilic Coating | 2000 | 3000 | 2000 | 2000 | 2000 | 3500 | 1000 | 2000 |
| Band Width A (μm) | | | | | | | | |
| Edge Stain Property | A | A | C | A | C | A | A | A |
| Edge Scumming | A | A | C | B | A | B | B | B |
| Property | | | | | | | | |

TABLE III

| | Sample No. | | |
|---|---|---|---|
| | Comparative | Comparative | Comparative |
| | Example 13 | Example 14 | Example 15 |
| Desensitizing Solution | None | None | Solution G |
| Droop Depth Y (μm) | 30 | 10 | 30 |
| Droop Width X (μm) | 1200 | 400 | 1200 |
| Hydrophilic Coating | 2000 | 2000 | 2000 |
| Band Width A (μm) | | | |
| Edge Stain Property | A | C | A |
| Edge Scumming | C | C | B |
| Property | | | |

The data (evaluations) presented in TABLES I and II indicate that lithographic printing plate precursors prepared for Invention Examples 1, 2, 3, and 4 exhibited little or no edge stain and edge scumming during lithographic printing while exhibiting little or no damage to the photosensitive radiation-sensitive imagable layer. The inventive precursors also exhibited good printing run length, background sensitivity, imaging speed, shelf life. The hydrophilic coating band applied to each of such precursors had excellent appearance, well controlled width, and well controlled thickness.

However, the precursors prepared outside the present invention, such as Comparative Examples 1 and 8 exhibited inferior edge scumming due to the lack of an amphoteric surfactant in the hydrophilic coating band provided using Solution B and Solution E. Moreover, the precursors of Comparative Examples 2 and 9 exhibited inferior edge stain because of the shear droop depth Y was too small. In contrast, the precursors prepared outside the present invention for Comparative Examples 3 and 10 exhibited inferior edge scumming because the shear droop depth Y was too large and led to crucial cracks on opposing edges of the precursors. In addition, the precursors prepared outside the present invention for Comparative Examples 4 and 11 also exhibited inferior edge scumming because the hydrophilic coating band on the opposing edges was not wide enough to prevent edge scumming. The precursors with suitable edge droop width X and depth Y without a hydrophilic coating band showed inferior edge scumming properties, although they showed superior edge stain properties as shown in Comparative Examples 6 and 13. Additionally, the precursors of Comparative Examples 7 and 14 that had unsuitable edge droop and no hydrophilic coating band exhibited not only inferior edge scumming properties but also inferior edge stain properties. The precursors of Comparative Examples 5, 12, and 15 showed unsatisfactory edge scumming properties due to low concentrations of amphoteric surfactants in the hydrophilic coating bands derived from Solutions C, F, and G. In Comparative Example 15, the addition of the anionic surfactant Pelex NBL did not improve the edge scumming properties, even though the total amount of amphoteric surfactants and anionic surfactant in the dried hydrophilic coating band derived from Solution G is the same as the amount of amphoteric surfactant derived from Solution D.

The invention has been described in detail with particular reference to certain preferred embodiments thereof, but it will be understood that variations and modifications can be effected within the spirit and scope of the invention.

### PARTS LIST

1 lithographic printing plate precursor
2 substrate
3 opposing edge
4 anodic oxide layer
5 radiation-sensitive imagable layer
6 hydrophilic coating band
7 shear droop
8 precursor outermost surface
9 extended line from precursor outermost surface
10 protective layer
12a, 12b overlapping rotary blades
14 continuous radiation-sensitive web
16 slitting device
18 radiation-sensitive strips
20 hydrophilic coating band formulation
22 opposing edge
24 microspray gun nozzle
26 air pressure controller
28 hydrophilic coating band
30 air flow guide
32 drying air
34 hydrophilic coating solution tank
36 flowmeters
A hydrophilic coating band width
c clearance distance
d overlapping distance
X shear droop width
Y shear droop depth
Z direction of movement

1. A negative-working lithographic printing plate precursor comprising:
a substrate comprising a hydrophilic surface and two opposing edges having edge surfaces;
a negative-working radiation-sensitive imagable layer that is disposed on the hydrophilic surface of the substrate, the negative-working radiation-sensitive imagable layer comprising:
one or more free radically polymerizable components,
an initiator composition that provides free radicals upon exposure of the radiation-sensitive imagable layer to radiation,
one or more radiation absorbers, and
optionally, a polymeric binder different from the one or more free radically polymerizable components;
wherein the negative-working lithographic printing plate precursor has al shear droop at each of the two opposing edges, which shear droop has a shear droop depth Y of at least 20 μm and up to and including 200 μm, and a shear droop width X of at least 500 μm and up to and including 2000 μm, and
wherein the negative-working lithographic printing plate precursor further comprises a band of a hydrophilic coating disposed over the negative-working radiation-sensitive imagable layer and any protective layer disposed thereon, which hydrophilic coating band extends from each of the two opposing edges inwardly along the hydrophilic surface independently for hydrophilic coating band width A to be at least 1.5 times the shear droop width X, wherein the hydrophilic coating band comprises one or more amphoteric surfactants in a total amount of at least 5 weight % and up to and including 90 weight %, based on the total dry weight of the hydrophilic coating band, which total amount of the one or more amphoteric surfactants is greater than the total of all cationic, anionic, and nonionic surfactants in the hydrophilic coating band,
and the negative-working lithographic printing plate precursor optionally comprises a protective layer disposed over the negative-working radiation-sensitive imagable layer.

2. The negative-working lithographic printing plate precursor of claim 1, wherein the shear droop has a shear droop depth Y of at least 50 μm and up to and including 150 μm, and a shear droop width X of at least 750 μm and up to and including 1500 μm.

3. The negative-working lithographic printing plate precursor of claim 1, wherein the hydrophilic coating band is disposed over the negative-working radiation-sensitive imagable layer and any protective layer disposed thereon, from each of the two opposing edges inwardly along the hydrophilic surface independently for hydrophilic coating band width A of at least 200 μm and up to and including 4,000 μm.

4. The negative-working lithographic printing plate precursor of claim 1, where the hydrophilic coating band is essentially free of anionic, cationic, or nonionic surfactants.

5. The negative-working lithographic printing plate precursor of claim 1, wherein the hydrophilic coating band further comprises one or more hydrophilic film-forming polymers in an amount of at least 10 weight %, based on the total dry weight of the hydrophilic coating band.

6. The negative-working lithographic printing plate precursor of claim 1, wherein the hydrophilic coating band further comprises one or more hydrophilic film-forming polymers, each of which is represented by either of the following Structure (Ia) or Structure (Ib): 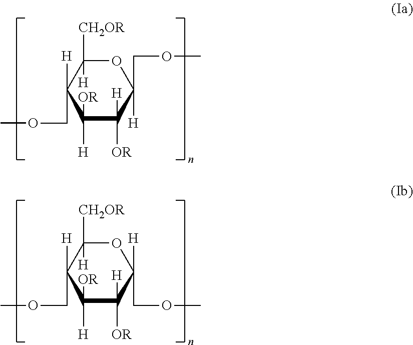
wherein R represents hydrogen, an alkyl group having 1 to 4 carbon atoms, a —CH₂C(═O)OM group, or a —(CₘH₂ₘO)ₓH group; M represents hydrogen or an alkali metal ion; m represents an integer of from 2, 3, or 4; n and x independently represent an integer of 1 or more; provided that the three R groups in Structure (Ia) or (Ib) have a total substitution degree of from 0.5 and up to and including 3.

7. The negative-working lithographic printing plate precursor of claim 1, wherein the one or more amphoteric surfactants are independently represented by the following Structure (V): 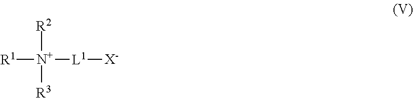
wherein R¹ represents a substituted or unsubstituted alkyl group having 1 to 24 carbon atoms, which substituted or unsubstituted alkyl group is directly connected to the positive-charged nitrogen atom or is indirectly connected to the positively-charged nitrogen atom through a hetero connecting group; R² and R³ independently represent hydrogen or a substituted or unsubstituted alkyl group having 1 to 5 carbon atoms; L¹ represents a substituted or unsubstituted aliphatic linking group having 1 to 4 atoms in the chain; and X⁻ represents an anionic group or a salt thereof.

8. The negative-working lithographic printing plate precursor of claim 7, wherein R¹ is a substituted or unsubstituted alkyl group having 8 to 18 carbon atoms and is connected to the nitrogen atom through an amide linkage —C(═O)NR⁴-L²-; R², R³, and R⁴ independently represent hydrogen or a substituted or unsubstituted alkyl group having 1 to 3 carbon atoms; L¹ and L² independently represent a substituted or unsubstituted alkylene group having 1 to 3 carbon atoms; and X⁻ represents a carboxy, carboxylate, sulfo, sulfate, phospho, or phosphate group.

9. The negative-working lithographic printing plate precursor of claim 1 that is on-press developable using a lithographic printing ink, a fountain solution, or a combination of a lithographic printing ink and a fountain solution.

10. The negative-working lithographic printing plate precursor of claim 1 that is rectangular in shape.

11. The negative-working lithographic printing plate precursor of claim 1, wherein the negative-working radiation-sensitive imagable layer comprises two or more free radically polymerizable components.

12. The negative-working lithographic printing plate precursor of claim 1, wherein the negative-working radiation-sensitive imagable layer comprises one or more polymeric binders, at least one of which polymeric binders is present as particles having an average particle size of at least 50 nm and up to and including 400 nm.

13. The negative-working lithographic printing plate precursor of claim 1, further comprising crosslinked polymeric particles having an average diameter of at least 2 μm, which crosslinked polymeric particles are present either in the negative-working radiation-sensitive imagable layer, the protective layer when present, or in both the negative-working radiation-sensitive imagable layer and the protective layer when present.

14. The negative-working lithographic printing plate precursor of claim 1, wherein the negative-working radiation-sensitive imagable layer is an infrared radiation-sensitive imagable layer, and the one or more radiation absorbers are one or more infrared radiation absorbers.

15. The negative-working lithographic printing plate precursor of claim 1, wherein the substrate comprises an anodic oxide layer underneath the negative-working radiation-sensitive imagable layer.

16. A method for forming a lithographic printing plate, comprising:
A) imagewise exposing a negative-working lithographic printing plate precursor according to claim 1 with radiation, to provide imagewise exposed regions and non-imagewise exposed regions in the negative-working radiation-sensitive imagable layer; and
B) removing the non-imagewise exposed regions of the negative-working radiation-sensitive imagable layer.

17. The method of claim 16, wherein the negative-working lithographic printing plate precursor comprises one or more polymeric binders in the negative-working radiation-sensitive imagable layer, at least one of which polymeric binders is present as particles having an average diameter of at least 50 nm and up to and including 400 nm; and
B) removing the non-imagewise exposed regions of the negative-working radiation-sensitive imagable layer is carried out on-press using a lithographic printing ink, a fountain solution, or a combination of a lithographic printing ink and a fountain solution.

18. The method of claim 16, wherein the imagewise exposing radiation is infrared radiation.
